(19) United States
(12) Patent Application Publication
(10) Pub. No.: US 2018/0180655 A1
(43) Pub. Date: Jun. 28, 2018

(54) ULTRA-LOW NOISE PHOTONIC PHASE NOISE MEASUREMENT SYSTEM FOR MICROWAVE SIGNALS

(71) Applicant: IMRA America, Inc., Ann Arbor, MI (US)

(72) Inventors: Naoya Kuse, Longmont, CO (US); Martin E. Fermann, Dexter, MI (US); Antoine Jean Gilbert Rolland, Longmont, CO (US)

(21) Appl. No.: 15/901,186

(22) Filed: Feb. 21, 2018

Related U.S. Application Data
(63) Continuation-in-part of application No. PCT/US2017/045450, filed on Aug. 4, 2017.
(60) Provisional application No. 62/382,609, filed on Sep. 1, 2016.
(60) Provisional application No. 62/419,646, filed on Nov. 9, 2016.
(60) Provisional application No. 62/462,591, filed on Feb. 23, 2017.

(51) Int. Cl. G01R 29/26; G01R 31/28; H04B 10/63

(52) U.S. Cl. CPC G01R 29/26; H04B 2210/006; H04B 10/63; G01R 31/2824

(57) ABSTRACT

Systems and methods for precision phase noise measurements of radio frequency (RF) oscillators are provided. An RF signal under test can be modulated on a continuous wave (cw) laser carrier frequency via generation of modulation sidebands using an appropriate modulator. A photonic delay line can be implemented as a self-heterodyne detection system for the phase noise, allowing for photonic down-conversion of the phase noise measurement to direct current (DC). The self-heterodyne detection system allows detection outside of any 1/f noise issues. Ultra-low phase noise detection for RF frequencies in a range from below 1 GHz to beyond 100 GHz is enabled with a low noise floor in the whole frequency range. Higher-order modulation sidebands can further reduce the noise floor of the system. Ultra-low noise RF (microwave) output can be generated. The RF signal under test can be generated by a dielectric resonance oscillator or opto-electronic oscillator.

### CROSS-REFERENCE TO RELATED APPLICATIONS

This application is a continuation-in-part of international application no. PCT/US2017/045450, filed Aug. 4, 2017, which claims the benefit of priority to U.S. patent application Ser. No. 62/382,609, filed Sep. 1, 2016, U.S. patent application Ser. No. 62/419,646, filed Nov. 9, 2016, and U.S. Patent Application No. 62/462,591, filed Feb. 23, 2017, all of which are entitled ULTRA-LOW NOISE PHOTONIC PHASE NOISE MEASUREMENT SYSTEM FOR MICROWAVE SIGNALS; all of the foregoing are hereby incorporated by reference herein in their entireties for all they disclose so as to form a part of this specification.

### BACKGROUND

### Field

The present disclosure relates to the construction of an ultra-low noise photonics phase noise measurement system for microwave signals.

### Description of the Related Art

With recent advances in low phase noise microwave technology, the measurement of phase noise is becoming increasingly difficult and cumbersome with conventional technologies.

### SUMMARY

Progress in ultra low phase noise microwave generation depends on ultra low phase noise characterization systems. However, achieving high sensitivity currently typically relies on time consuming averaging via cross correlation, which sometimes even underestimates phase noise because of residual correlations. Moreover, extending high sensitivity phase noise measurements to microwaves frequencies beyond 10 GHz is difficult because of the lack of suitable high frequency microwave components.

In this disclosure, examples of a delayed self-heterodyne method in conjunction with sensitivity enhancement via the use of higher order comb modes from an electro-optic comb for ultra-high sensitivity phase noise measurements are described. The method can reduce or obviate the use of high frequency radio frequency (RF) components and can have a frequency measurement range limited, in some cases, only by the bandwidth (e.g., 100 GHz) of current electro-optic modulators. In some embodiments, the estimated noise floor is as low as −133 dBc/Hz, −155 dBc/Hz, −170 dBc/Hz and −171 dBc/Hz without cross correlation at 1 kHz, 10 kHz, 100 kHz and 1 MHz Fourier offset frequency for a 10 GHz carrier, respectively. Moreover, since no cross correlation is necessary in some embodiments, RF oscillator phase noise can be directly suppressed via feedback up to about a 100 kHz frequency offset.

The present disclosure also describes examples of photonic systems adapted to ultra-high sensitivity phase noise measurements. For example, photonics down conversion of high frequency microwave signals provides a novel approach for phase noise detection with an ultra-low phase noise floor.

In an example embodiment, a continuous wave (cw) laser at a carrier frequency is modulated with an electro-optic modulator driven by a microwave signal to be tested. The microwave signal has a fixed frequency and also contains low level phase noise, which is to be measured. The microwave signal imparts side-bands to the cw laser frequency in the optical frequency domain separated by the frequency of the microwave signal. These sidebands contain the information about the phase noise of the microwave signal and are analyzed.

In the example embodiment, a photonic delay line is implemented as a self-heterodyne detection system for the phase noise, where a frequency sideband of the modulated signal is interfered with a time-delayed replica of itself, generating a first homodyne signal. This interference can for example be obtained with the use of an imbalanced interferometer (e.g., a Mach-Zehnder interferometer). The effect of fiber noise at the carrier frequency can be alleviated by interfering the signal at the carrier frequency with a time-delayed replica of itself in the same interferometer, generating a second homodyne signal. By mixing the first and second homodyne signals in a microwave mixer, the noise at the carrier frequency is cancelled, leaving only the phase noise at the microwave signal.

The self-heterodyne method can be used to avoid 1/f noise in the photo-detection system, where the carrier frequency and its sideband are further shifted by a frequency shifter in one of the two arms of the interferometer. Appropriate optical filters and a microwave mixer can be used to isolate the phase fluctuations of the microwave signal from the phase noise of the fiber.

The system allows for ultra-low phase noise detection for radio frequency (RF) frequencies in a range from below 1 GHz up to and beyond 100 GHz, limited only by the bandwidth of the optical filter used for carrier and sideband isolation on the one hand and the modulation capability of the electro-optic modulator.

To extend the sensitivity of the system, higher-order sidebands of a comb (e.g., an electro-optic (EO) comb) can be generated by the electro-optic modulator. Since phase noise power increases quadratically with respect to the sideband order, a much lower noise floor can so be obtained.

To extend the sensitivity even further the signal to be measured can be coupled into two independent un-correlated systems, the base-band signal can then be analyzed by a two channel fast Fourier transform (FFT) analyzer and a numeric cross correlation between the channels performed. This allows for a further reduction in noise floor proportional to the square root of the number of acquired FFT traces.

When using the phase noise measurement system in real time, it can further be applied to the reduction of phase in a low-noise microwave oscillator via direct feedback. A variety of microwave oscillators such as dielectric resonator oscillators or opto-electronic oscillators can be improved this way.

As yet another alternative use of the phase noise measurement system, it can be used to lock two cw lasers to each other, allowing for low noise millimeter (mm) wave generation via heterodyning those two cw lasers on an optical-to-electrical converter (OEC) such as a photodetector.

The foregoing summary and the following drawings and detailed description are intended to illustrate non-limiting examples but not to limit the disclosure.

### BRIEF DESCRIPTION OF THE DRAWINGS

FIG. 1 schematically illustrates an embodiment of a phase noise analyzer system configured to generate tunable low phase noise microwaves.

FIG. 2A shows a schematic of the working principle for an embodiment of a phase noise analyzer.

FIG. 2B shows a setup of an example implementation of a phase noise analyzer.

FIG. 2C shows examples of an optical spectrum (intensity in dB versus wavelength in nm) of an electro-optic (EO) comb after the phase modulator (PM) (upper curve) and optical spectra after the optical band pass filters (BPFs) (lower pair of curves showing a pair of EO comb modes) from the example phase noise analyzer shown in FIG. 2B.

FIG. 2D shows an example of the single sideband (SSB) phase noise PSD as a function of Fourier frequency offset for a DUT (10 GHz carrier frequency) as measured with a 1 km fiber delay and an example of the SSB phase noise PSD for a conventional delayed self-homodyne system. The two SSB phase noise PSD curves nearly completely overlap for Fourier frequency offsets between 10² Hz and 10⁵ Hz.

FIG. 2E shows example measurements of SSB phase noise PSDs of two different microwave devices under test (DUTs) with about 20 GHz carrier frequency.

FIG. 3A shows an example phase noise analyzer using self-heterodyne detection with a photonic delay line.

FIG. 3B shows another example of a phase noise analyzer using self-heterodyne detection with a photonic delay line.

FIG. 4A shows an example of an RF power spectrum obtained from an embodiment of a phase noise analyzer.

FIG. 4B shows an example of phase noise (upper curve) measured with an embodiment of the phase noise analyzer as well as an estimated noise floor (lower curve) of the phase noise measurement.

FIG. 5 shows the principle of phase noise sensitivity enhancement via the use of higher order sidebands of the modulator.

FIG. 6A demonstrates an example of the phase noise sensitivity enhancement obtainable via the use of higher-order modulation sidebands in an embodiment of the phase noise analyzer.

FIG. 6B shows examples of single sideband (SSB) phase noise sensitivity limits versus frequency offset for a 1 km fiber delay for an example phase noise analyzer.

FIG. 7 schematically illustrates an embodiment of the phase noise analyzer further utilizing cross correlation and signal averaging for reduction of the noise floor.

FIG. 8 schematically illustrates an embodiment of a fiber delay line implemented for tunable low phase noise microwave generation.

FIG. 9A schematically illustrates an embodiment of a fiber delay line implemented for phase locking of two cw lasers and high frequency microwave generation.

FIG. 9B schematically illustrates an alternative embodiment of a fiber delay line implemented for phase locking of two cw lasers and high frequency microwave generation.

FIG. 9C schematically illustrates yet another embodiment of a fiber delay line implemented for phase locking of two cw lasers and high frequency microwave generation.

FIG. 9D schematically illustrates an embodiment of a system for generating low noise microwaves, which may be used for microwave spectral analysis.

FIG. 9E schematically illustrates an embodiment of a system for the generation of low noise frequency-modulated microwaves.

FIG. 10A schematically illustrates an embodiment of a tunable optoelectronic oscillator (OEO) adapted for feedback control.

FIG. 10B schematically illustrates a filter response of a broadband RF filter and a sinusoidal RF filter constructed in the optical domain.

FIG. 10C schematically illustrates the combined filter response of the two RF filters shown in FIG. 10B.

FIG. 11 schematically illustrates an embodiment of a frequency synthesizer based on a tunable OEO and a high sensitivity phase noise analyzer (PNA).

FIG. 12 is a graph that shows an example of a phase noise PSD obtained from the locked OEO described with reference to FIG. 11.

FIG. 13 schematically illustrates an example of a phase noise analyzer locked to an external frequency reference.

FIG. 14 schematically illustrates an example of an OEO locked to an optical frequency reference.

FIG. 15 schematically illustrates an example of a system configured to generate millimeter or terahertz waves.

The figures depict various embodiments of the present disclosure for purposes of illustration and are not intended to be limiting. Wherever practicable, similar or like reference numbers or reference labels may be used in the figures and may indicate similar or like functionality.

### DETAILED DESCRIPTION

### Overview

Microwave photonics is a rapidly expanding field for handling the explosive growth of data rates as found in broadband wireless communication, radar, satellite communication, and electric warfare systems, greatly improving the operational frequency and bandwidth. Since spectral purity, e.g. phase noise, of microwaves sets the ultimate performance limits of radio frequency (RF) links, great efforts have been expended for low noise microwave generation, including methods based on optoelectronic oscillators (OEOs), optical frequency division (OFD), electro-optic (EO) combs, Kerr combs, and Brillouin lasers. Among them, OFD incorporating ultra-low noise frequency combs has resulted in extremely spectrally pure microwaves at a 12 GHz carrier frequency, achieving a phase noise <−170 dBc/Hz, although the carrier frequency is limited to harmonics of the repetition frequency of the comb.

Actively suppressing phase noise of RF oscillators is a more general way for the generation of low noise RF microwaves at arbitrary carrier frequencies. For this, real time high sensitivity measurement of phase noise is implemented, since the measurement sensitivity sets the ultimate achievable phase noise. Real time high sensitive phase noise measurement systems can also simplify the characterization of ultra-low phase noise signals, reducing or eliminating the need for the cross correlation method. Data acquisition times for phase noise estimates can be greatly reduced and the issue with possible underestimation of phase noise can be eliminated.

Conventionally, phase noise can be characterized via mixing of two microwave signals, regardless of whether cross correlation is used or not. In addition to the device under test (DUT), a second low noise microwave reference source can be used, which can be synchronized to the DUT. After mixing, the phase noise can be down-converted to direct current (DC) and can be measured by a signal analyzer. The phase noise of the microwave reference should further be lower than that of the DUT to enable meaningful measurements. These two above constraints are generally difficult to satisfy without extensive experimental complexity.

To overcome these difficulties, a photonics-based delayed self-homodyne technique can be used. In the photonics-based delayed self-homodyne technique, a photonic delay is used as a frequency discriminator instead of an RF delay line to reduce or minimize propagation loss and sensitivity to electromagnetic interference. The sensitivity of the self-homodyne method can reach in some implementations about −145 dBc/Hz, −153 dBc/Hz, and −158 dBc/Hz for a 10 GHz carrier at 10 kHz, 100 kHz, and 1 MHz Fourier frequency offset, respectively, without implementation of cross correlation. For both methods, all components which are used for optical to electronic (O/E) or electrical to optical (E/O) conversion, RF amplifiers, RF phase shifters, RF isolators, and RF mixers etc., should have a bandwidth larger than that of the DUT frequency. Making RF components with low noise and more than 10 GHz bandwidth is very difficult. The high bandwidth requirement of the RF detection system indeed limits the possible phase noise sensitivity and measurable DUT frequency. The foregoing difficulties can be a serious impediment to phase noise measurements at high microwave frequencies.

Recently, a photonic down-conversion technique without the need for a large bandwidth photo detector (PD) and RF mixer has been demonstrated, in which two electro-optic modulators (EOM)s are used, and a photonic delay is installed between the two EOMs. In this method, because the DUT frequency is downconverted to DC in the optical domain, not via an RF mixer, it does not rely on large bandwidth components. Moreover, the sensitivity of the method is independent of the DUT frequency unless it reaches the fundamental limit from delay fiber noise at the DUT frequency. However, the demonstrated sensitivity of −137 dBc/Hz at 10 kHz frequency offset for a 10 GHz carrier, which is probably limited by background noise such as electronic and shot noise, has not been as good as achievable with the photonics-based delayed self-homodyne method.

These techniques can be extended to high frequencies (e.g., frequencies greater than 10 GHz, greater than 20 GHz, and up to about 100 GHz in various embodiments). Since the techniques can exploit self-heterodyning as well as sensitivity enhancement via the use of high-order sidemodes from an EO comb, both high sensitivity and high frequency capability can be retained simultaneously in some embodiments. In various experiments, −155 dBc/Hz, −170 dBc/Hz and −171 dBc/Hz sensitivity for a 10 GHz carrier at 10 kHz, 100 kHz, and 1 MHz, respectively, were demonstrated. In addition, by taking advantage of real time high sensitivity, active phase noise reduction of an RF oscillator is also demonstrated.

High-Level Example RF Generator and Phase Noise Analyzer

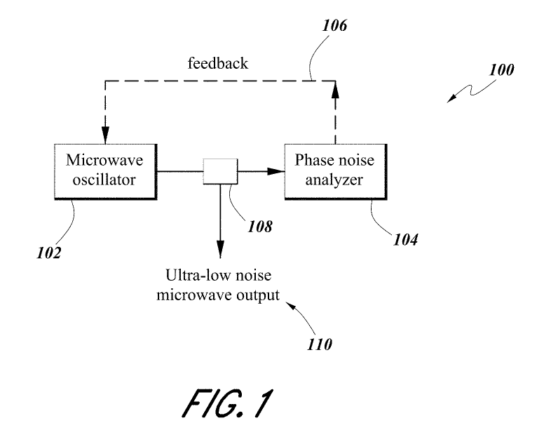

FIG. 1 is a high level block diagram that schematically illustrates an embodiment of a low phase noise RF generator 100 configured to generate tunable low phase noise microwaves. The RF generator 100 can provide real time, high sensitivity phase noise measurements, e.g. without necessarily relying on cross correlation. The RF generator 100 generally comprises a microwave oscillator 102 (e.g., a device under test (DUT)), a phase noise analyzer 104, a feedback loop 106, and a microwave splitter 108 configured to extract the ultra-low noise microwave output 110. The microwave oscillator 102 can be a dielectric resonator oscillator (DRO), a tunable opto-electronic oscillator (OEO), a tunable coupled OEO (COEO), or another type of RF microwave source, alone or in combination. As will be described below, the phase noise analyzer 104 can measure or control noise in the output of the microwave oscillator 102 leading to the generation of the ultra-low noise output 110. For example and as will be further described below, the feedback loop 106 can be configured to use output of an RF mixer as an error signal, which is used to feed back a control signal to the microwave oscillator under test 102, thereby reducing the phase noise of the microwave oscillator 102. Since the possible phase noise reduction of an RF oscillator via feedback may be limited because of limited gain, it may be advantageous to use an RF oscillator at the lowest possible noise level for obtaining a system with low RF phase noise. By using RF oscillators 102 with intrinsically low phase noise, embodiments of the disclosed low phase noise analyzers 104 can produce microwave output having a phase noise of −100 dBc/Hz within 100 Hz of the carrier frequency or even lower.

In an embodiment of the phase noise analyzer 104, a continuous wave (cw) laser at a carrier frequency is modulated with an electro-optic modulator (EOM) driven by a microwave signal from the DUT 102 to be tested. The microwave signal has a fixed frequency and also contains low level phase noise, which is to be measured by the phase noise analyzer 104. The microwave signal imparts sidebands to the cw laser frequency in the optical frequency domain separated by the frequency of the microwave signal. These sidebands contain the information about the phase noise of the microwave signal and are analyzed and fed back via the feedback loop 106 to reduce the phase noise of the oscillator 102.

Further details and experimental results relating to embodiments of low phase noise analyzers will now be described.

Working Principles and Example Phase Noise Analyzer

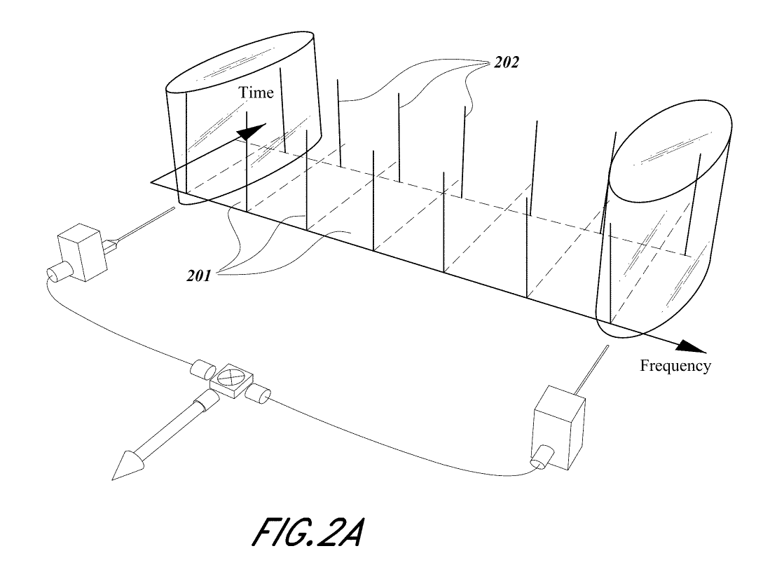

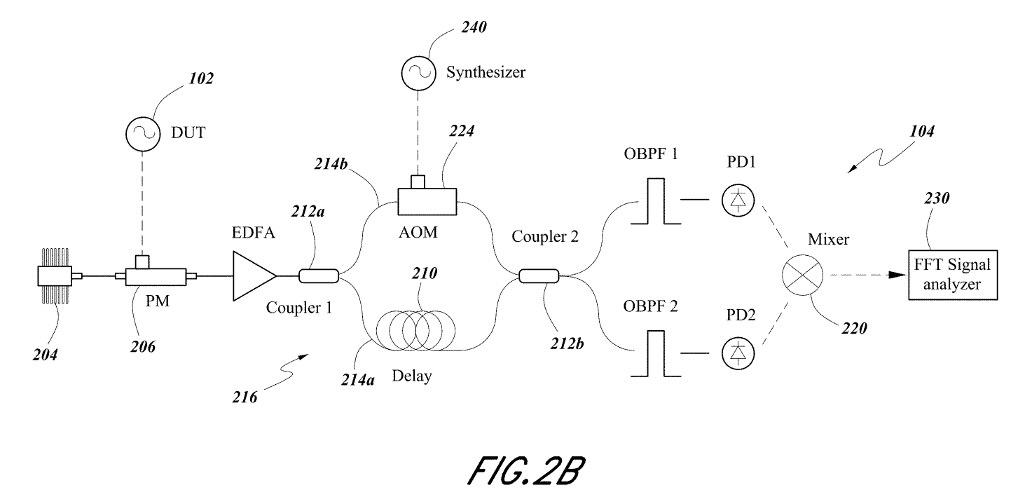

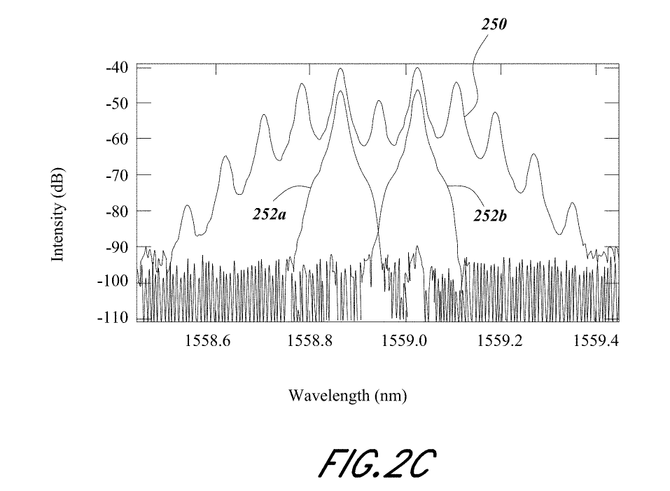

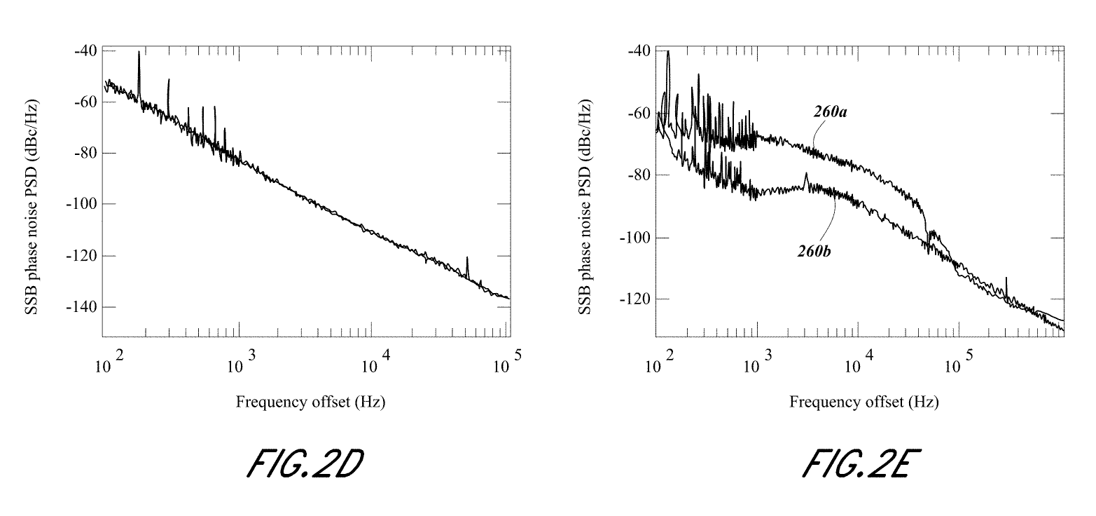

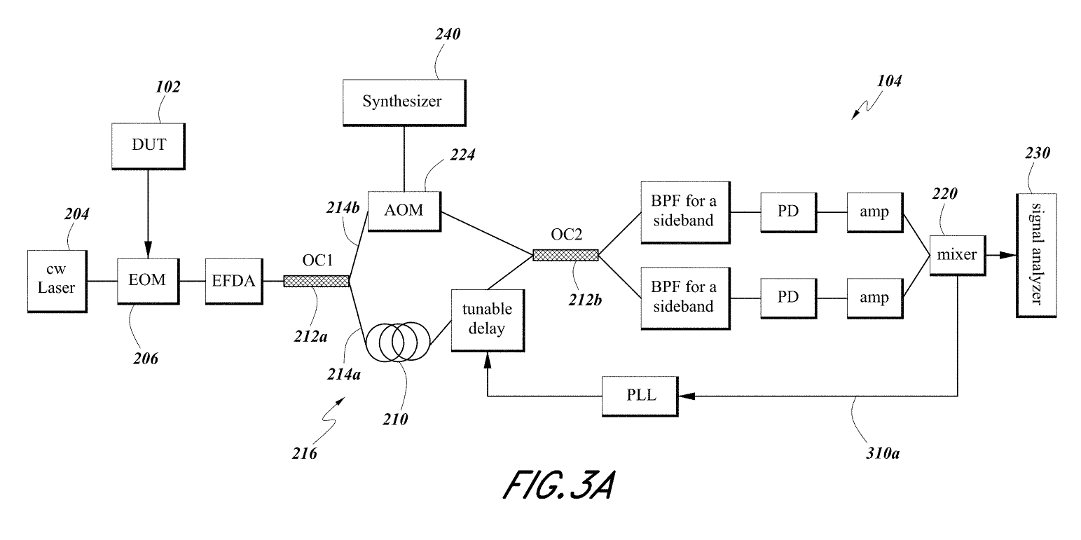

FIG. 2A shows a schematic of the working principle for an embodiment of a phase noise analyzer. Pairs (highlighted by oval cylinders) of frequency-shifted 201 and time delayed 202 EO combs are photo-detected, mixed, and analyzed. Additional details of the working principle are described with reference to FIGS. 2B and 5.

FIG. 2B shows a setup of an example implementation of a phase noise analyzer. The phase noise analyzer 104 includes a continuous wave (cw) laser 204, a device under test (DUT) 102, a phase modulator (PM) 206, an erbium (Er) doped fiber amplifier (EDFA), an acousto-optic modulator (AOM) 224, optical bandpass filters (OBPF1 and OBPF2), and optical-to-electrical converters (OEC), which can be photodetectors (PD1 and PD2). The example phase noise analyzer 104 of FIG. 2B uses a two wavelength delayed self-heterodyne interferometer 216. An EO comb is generated when the continuous wave (cw) laser 204 with 1560 nm center wavelength passes the phase modulator (PM). The phase modulator 206 is modulated by an RF device under test (DUT) 102 with around 10 GHz or 20 GHz, generating up to +/−10th comb harmonics (also referred to herein as modes or sidebands).

Phase noise of the +/− n-th EO comb mode is represented as φ_{cw}(t)±n φ_{DUT} (t), where φ_{cw} (t) and φ_{DUT} (t) are phase noise of the cw laser 204 and the DUT 102 in the time domain, respectively, and n is the comb mode number (n is treated as zero or a positive integer). The EO comb is split into two arms 214a, 214b of the interferometer 216 by a 50:50 optical coupler 212a. One arm 214a is time delayed by a tunable photonic delay line comprising a coil of fiber 210 (e.g., about 100 m or 1 km in various examples), and the other arm 214b is frequency-shifted by, e.g., an acousto-optic modulator (AOM) 224 driven by a synthesizer 240.

After this process, the two EO combs from the arms 214a, 214b are interfered by a 2×2 optical coupler 212b. Two outputs from the optical coupler 212b are optically bandpass filtered by OBPF1 and OBPF2 to extract only a pair of EO comb modes, e.g. the +/− n-th EO comb mode pair. Subsequently, the extracted pairs of EO comb modes are photodetected by the photodetectors PD1 and PD2. At the photodetectors PD1, PD2, beat signals at the AOM frequency are obtained. The signals contain phase noise from the fiber delay line, AOM 224, the cw laser 204, and the DUT 102. Note that because the frequency of the detected signal is at the heterodyne frequency, e.g. AOM frequency (at about 100 MHz in some cases), this example system does not require a large bandwidth for photodetection or any of the downstream RF components, unlike the high bandwidths required for the conventional delayed self-homodyne systems. By mixing two signals with an RF mixer 220 at quadrature, the voltage noise power spectrum density (PSD) of the signal from the RF mixer (Vₒᵤₜ (f)²) can be determined by a fast Fourier transform (FFT) signal analyzer 230 to be

Vₒᵤₜ(f)²=K₁(2n)²|H(if)|²L_{DUT}(f) (1).

In Equation (1), K₁ is a coefficient which connects phase noise power spectrum density with voltage noise power spectrum density, whereas f , H (jf), and L_{DUT} (f) are the Fourier frequency offset, delay transfer function, and SSB (single sideband) phase noise PSD of the DUT, respectively. At the RF mixer 220, phase noise of the cw laser 204 and the AOM 224 is cancelled out, and fiber noise is down-converted from the optical to the DUT frequency. Without intending to be bound by or limited by any particular mathematical theory, a detailed derivation of Equation (1) is provided in U.S. patent application Ser. No. 62/462,591, filed Feb. 23, 2017, which is hereby incorporated by reference herein in its entirety. The expression in Equation (1) is the same as can be derived for the delayed self-homodyne method, except for the (2n)² factor. At least because of the (2n)² factor, the sensitivity is enhanced by 20×log(2n) dB until the sensitivity reaches the limit set by the fiber delay line. In other words, phase noise of the DUT is enhanced, while contributions to phase noise from background noise (including electronic and shot noise), residual cw phase noise and amplitude modulation—phase modulation (AM-PM) conversion through the system remain the same. More details are discussed in the following sections.

With further reference to the embodiment illustrated in FIG. 2B, which was used to generate the experimental results described below with reference to FIGS. 2D and 2E, the cw laser 204 can have a linewidth of 1.8 kHz, 10 mW output power, and 1558.94 nm wavelength (e.g., a RIO ORION laser module available from Rio Redfern Integrated Optics, Santa Clara, CA). The 10 GHz DUT 102 (e.g., an INWAVE AG, Switzerland, Dielectric Resonator Oscillator DRO-10010) produces about +10 dBm output power and has a modulation bandwidth of more than 500 kHz. In many experimental examples described herein, up to +/−10th harmonics (n=10) are exploited (but this is for illustration and is not a limitation to the scope of the systems). To generate +/−10th harmonics with optimum mode power, 3.7 π rad phase modulation is used in this system, which corresponds to about 33 dBm of power applied to the phase modulator PM. Because of this, an RF amplifier with up to +35 dBm output power can be installed between the DUT and the phase modulator. After generation of the EO comb, the EO comb is amplified by the EDFA (although other types of amplifiers can be used). The output power from the EDFA is 32 mW, 59 mW, and 115 mW when used in conjunction with the +/−1st, +/−3rd, and +/−10th EO comb modes (n=1, 3, 10), respectively, which generate signals of about -26 dBm RF power at the photodetectors PD1, PD2. Note additional optical amplifiers can also be included between coupler 2 and the two photo-detectors to further boost the optical power impinging on the photodetectors PD1 and PD2.

With continued reference to FIG. 2B, the amplified EO comb is split into two arms, 214a, 214b of the interferometer 216 by the 50:50 optical coupler 212a (although the splitting ratio may be different in other embodiments). In the second arm 214b, the EO comb is frequency shifted by about +80 MHz via the AOM 224. In the first arm 212a, the EO comb optionally passes through another AOM (not shown in FIG. 2B), configured for a frequency shift of about −80 MHz, and also passes through the photonic fiber delay line 210 (with a length of about 100 m and 1 km in examples described herein although any length in a range from about 10 m to about 10 km or more can be used). In principle, the implementation of only one AOM frequency shifter 224 should be sufficient. However, it was found that without an additional AOM (in the other arm 214a), spurious signals originating from the non-diffracted light transmission through the AOM 224 (at around −60 dB) may potentially cause detrimental effects to the system. The inclusion of the second AOM effectively doubles the extinction ratio between diffracted and non-diffracted light transmission through the AOMs to around −120 dB. The fiber delay line 210 can be disposed in a box with 5 mm thickness aluminum with a sound absorbing foam inside. No vibration isolation board from the ground was installed, however, a vibration isolation board can be used in other embodiments. After light from both arms 214a, 214b are combined with a 4 port optical coupler 212b with a splitting ratio of 50:50, each output is directed through optical bandpass filters OBPF1, OBPF2 (e.g., Yenista Optics, Newbury Park, Calif., XTM-50 and Alnair Labs Corp., Tokyo, JP, BVF-300). The central wavelength of the optical bandpass filters is tunable, and the full-width-half-maximum (FWHM) bandwidth is less than 10 GHz in one embodiment. The bandpass filtered EO comb mode pairs are photodetected with commercially available photo detectors PD1, PD2 (e.g., Electro-optics Technology Inc., Traverse City, Mich., EOT, ET-3010). After photo detection, RF signals with 160 MHz carrier frequency are optionally RF amplified and filtered, and electronically mixed in the RF mixer 220. Quadrature at the RF mixer is ensured by adjusting optical delay or, for experimental convenience, the DUT frequency.

Example Experimental Results for Phase Noise Measurement

FIG. 2C shows an example of an optical spectrum of the EO comb after the phase modulator (PM) (curve 250) and after the optical BPFs (curves 252a, 252b showing a pair of EO comb modes) of the example phase noise analyzer 104 shown in FIG. 2B. The RF power for the phase modulator is adjusted to optimize the +/−1st comb mode power, and the center wavelength of the optical bandpass filters are set at +/−1st comb mode wavelengths. The optical spectra 252a, 252b after the optical BPFs exhibit more than 50 dB side-mode suppression.

FIG. 2D shows an example of the SSB phase noise PSD as a function of Fourier frequency offset for a DUT (10 GHz carrier frequency) as measured with a 1 km fiber delay (red curve). As a validation of the obtained phase noise, the SSB phase noise PSD for a conventional delayed self-homodyne system is also shown and nearly overlaps the PSD for the self-heterodyne system over the entire frequency range shown. As shown in FIG. 2D, the phase noise obtained with the two techniques has little discrepancy, which means the output from the RF mixer 220 follows the theoretical expression from Equation (1). To demonstrate the principle of the present phase noise measurement system for high RF frequencies, the phase noise of two DUTs with about 20 GHz carrier frequency was also measured. SSB PSDs are shown in FIG. 2E, where a 100 m fiber delay was used to extend the frequency offset range to 1 MHz. The DUT microwave generator for curve 260a was a Wiltron 6747A swept frequency synthesizer, and the DUT microwave generator for curve 260b was a Hewlett-Packard 8341A synthesized sweeper. The experimental setup was the same as used for the measurement for a DUT with 10 GHz carrier frequency (FIG. 2D), except for changing the RF amplifier before the phase modulator and tuning the bandpass filters to appropriate transmission wavelengths.

Additional experimental results by the inventors have demonstrated the (2n)² sensitivity enhancement of Equation (1) from using±n mode pairs for Fourier frequency offsets up to 100 kHz to 1 MHz, and these results have been described in in U.S. Patent Application No. 62/462,591, filed Feb. 23, 2017, which is hereby incorporated by reference herein in its entirety. Except for fiber delay noise, phase noise magnification of the DUT can be useful to reduce or minimize unavoidable noise contributions from other noises sources (e.g., background noise (either electronic noise or shot noise), residual phase noise of the cw laser because of imperfect cancellation, or unwanted AM-PM conversion through the system) to enhance the sensitivity, because only phase noise of the DUT is magnified in these experiments, while other noise contributions remain the same. Accordingly, experimental results have demonstrated, for example, that the sensitivity when using the +/−10th sidemodes (n=10) can be improved by 20 dB compared with using the +/−1st sidemodes (n=1). Also, embodiments of the disclosed phase noise analyzers can provide improved or high sensitivity in real time, without resorting to cross correlation. Because such embodiments use a real time method, the signal after the mixer can be used to suppress the phase noise of the DUT by feeding back to the DUT.

The (2n)² enhancement obtained from the use of higher order sidemodes of the EO comb improves the sensitivity in terms of background noise, residual phase noise of the cw laser, and AM-PM conversion noise; only the fiber nose is unaffected via the use of harmonics. For both 100 m and 1 km fiber delay lengths used in the experiments, the main limitation is either background noise or fiber delay noise. When low order sidemodes of the EO comb are used (e.g., n≈1) , background noise is the main limitation. When higher order sidemodes of the EO comb are utilized (e.g., n≥3 to 10 or more) the sensitivity reaches the fiber noise limits at low frequency offset. At high frequency offset, background noise still limits the sensitivity in these experiments, indicating the use of harmonics with n greater than 10 can enable even higher sensitivity. In summary of the experimental results, when 1 km (100 m) fiber delay length in conjunction with +/−10th harmonics are used, the sensitivity is −133 (−113) dBc/Hz, −155 (−135) dBc/Hz, −170 (−154) dBc/Hz and n.a. (−171) dBc/Hz at 1 kHz, 10 kHz, 100 kHz and 1 MHz Fourier offset frequency for a 10 GHz carrier.

Some embodiments of the disclosed phase noise analyzers do not rely on electronic and O/E components with high bandwidth. In some such embodiments, the phase noise reduction is compatible with microwave carrier frequencies limited only by the modulation bandwidth of the EOM, which can reach up to 100 GHz.

Additional Advantages of Various Embodiments of Phase Noise Analyzers

Sensitivity of embodiments of the disclosed phase noise analyzers can ultimately reach the fiber noise limit when using higher order sidemodes of the EO comb (e.g., n greater than a few to 10 or more). However, fundamental thermally limited fiber noise is far below the fiber noise of the example experimental setup, which indicates a well-designed enclosure for the system can improve the fiber noise as can use of a fiber that is much closer to the thermal noise limit than the fibers used in the experiments. Another way to reduce fiber noise is to actively stabilize the fiber to an ultra-low phase noise cw laser. This additional feedback loop can be easily added to the setup shown in FIG. 2B and is further described below. At the photodetector (PD) (up-stream from the mixer), a signal containing both fiber noise and phase noise of the cw laser can be accessed, which can be used as an error signal to stabilize the fiber to the cw laser.

Embodiments of the disclosed techniques can be extended to high frequency carriers. The sensitivity degrades compared with lower frequency carriers, if fiber noise is the main limiting factor determining sensitivity. The sensitivity degrades by 20×log(f_{DUT}/10 GHz) dB, compared with the sensitivity for a 10 GHz carrier. This degradation is much slower than exhibited by present-day phase noise analyzers based on microwave technology.

To use higher order modes, EO combs with high average power may be used to propagate through the delay fiber, which may cause degradation of the sensitivity via nonlinear effects such as stimulated Brillouin and Rayleigh scattering because of excess intensity noise and phase noise. Although stimulated Brillouin scattering scatters light in the backward direction, intensity noise of the forward-propagating beam becomes worse when the power of the propagating light approaches the threshold for stimulated Brillouin scattering. Since the threshold can be determined by the power per comb mode, even when increasing the average power with the use of higher-order comb modes, the power per EO comb mode can stay the same and not lead to the onset of stimulated Brillouin scattering. In fact, the inventors did not observe any excess intensity noise at elevated power levels in their experiments. Stimulated Rayleigh scattering may also cause excess phase noise by co-propagating with the EO comb. The phase noise PSD of the signal at the PD was measured while changing the input power to the fiber delay. No excess phase noise was observed at least up to 90 mW mode power when using a 1 km fiber delay line. Because a power of 90 mW far exceeds the typical saturation level of PDs, neither stimulated Brillouin nor Rayleigh scattering is expected to affect sensitivity. Moreover, embodiments of the phase noise analyzer are compatible with the use of a 10 km fiber delay length, allowing for further improvement in sensitivity at or below a frequency offset of 10 kHz. Because the threshold of stimulated Brillouin scattering is proportional to the inverse of fiber length, no excess noise is expected up to power levels of 9 mW for a 10 km fiber.

To generate up to +/−10th harmonics with increased or optimum mode power, about 33 dBm RF power was used for one example phase modulator, so that an RF amplifier with up to 35 dBm may be installed between the DUT and the phase modulator. Selecting an adequate RF amplifier in terms of the noise figure, gain, and output power can provide additive phase noise below −170 dBc/Hz above 10 kHz frequency offset. To reduce the required RF power, an erbium-doped fiber amplifier (EDFA) with higher output can be used, additionally or alternatively to optimizing specified harmonic sidebands (other types of amplifiers can be used as well). Additionally or alternatively, nonlinear spectrum broadening via four wave mixing (FWM) can also be implemented. In addition, phase modulators with ultra-low V π (the voltage V required to cause π phase change) have been developed and can be utilized.

Regarding phase noise reduction via feedback, the ultimate limitation may, in some embodiments, be the sensitivity of the disclosed techniques. In some embodiments, the obtained phase noise is limited by the sensitivity of the out-of-loop measurement. Another possible limit is the feedback bandwidth, e.g., feedback gain. Improving the feedback bandwidth may be difficult since it can be limited by the fiber length. To obtain lower phase noise, an RF oscillator with intrinsically low phase noise can be used. By using intrinsically low phase noise RF oscillators, −100 dBc/Hz at close to carrier frequency is feasible by carefully designing an environmental isolation system. Note that using intrinsically low phase noise RF oscillators may not be effective in conjunction with other methods for active phase noise suppression, for example based on the use of high harmonics of an EO comb, since the sensitivity may not be as good as the present techniques even when using sidemodes of an EO comb up to a harmonic order of 100.

The components for the photonic subsystem utilized for some embodiments of a phase noise analyzer 104 are all-fiber based, and there is no need for any sophisticated modules such as ultra-low noise optical frequency combs and cw lasers stabilized to ultra low noise cavities (although such modules can optionally be used). This can be a great benefit compared to alternative ultra-low noise fixed frequency microwave generation and characterization systems.

Thus, various embodiments of a low phase noise analyzer 104 based on a two wavelength, delayed self-heterodyne interferometer, in which high order sidemodes of an EO comb are utilized for sensitivity enhancement, are described herein. Some such embodiments can provide a sensitivity of −133 (−113) dBc/Hz, −155 (−135) dBc/Hz, −170 (−154) dBc/Hz and n.a. (−171) dBc/Hz at 1 kHz, 10 kHz, 100 kHz and 1 MHz Fourier offset frequency for a 10 GHz carrier, respectively, via 1 km (100 m) fiber. Embodiments of these techniques can be extended to higher frequency DUTs, while preserving high sensitivity, because the techniques do not require large bandwidth photo detectors nor high frequency RF components. Moreover, because the phase noise measurement system can have real time sensing capability, the measured signal can be efficiently implemented to reduce the phase noise of a DUT microwave oscillator. Embodiments of the phase noise analyzers can greatly simplify the characterization of ultra-low noise microwaves and offer exciting opportunities for many emerging applications that rely on readily available ultra-low phase noise microwaves.

### Example Phase Noise Analyzer

In light of the overview presented above, this application will now describe various particular implementations of phase noise analyzers. For example, embodiments of a highly sensitive phase noise analyzer using self-heterodyne detection with a photonic delay line can be used to generate low phase noise microwaves. Any of the described embodiments can be used in the RF generator 100 described with reference to FIG. 1.

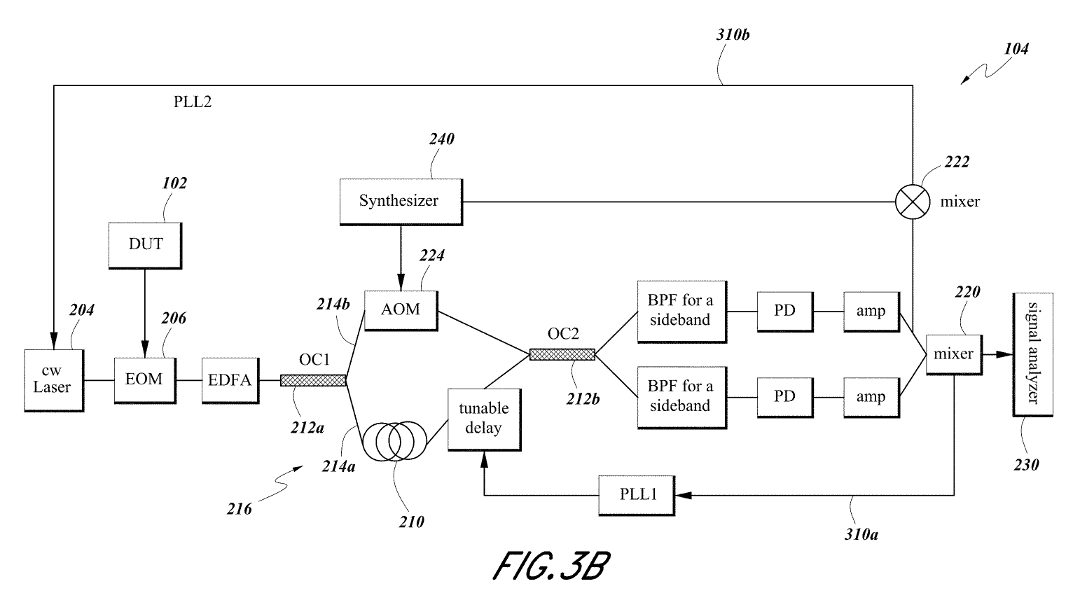

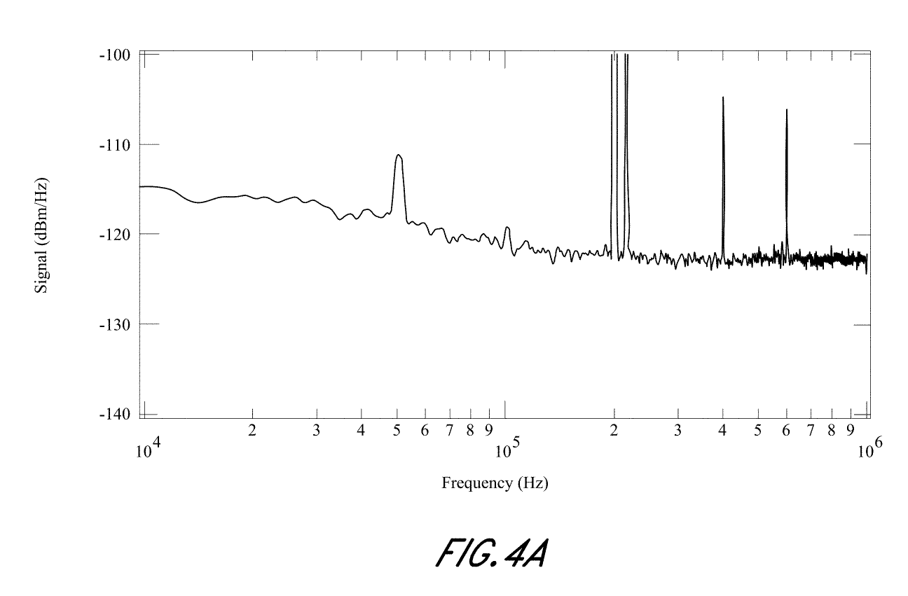

FIG. 3A schematically illustrates an embodiment of a phase noise analyzer 104. In this embodiment, the analyzer includes a cw laser 204 that is modulated by at least one phase modulator 206. The phase modulator 206 can comprise an electro-optic phase modulator (EOM). The EOM is modulated by the device under test (DUT) (e.g., an RF microwave oscillator), which produces a microwave signal generating sidebands to the cw laser, which contain the information of the DUT phase noise. More than one modulator, for example 2 or 3 EOMs can be cascaded to generate higher order sidebands with more power. The phase difference between EOMs can be an integer multiple of 2π, which can be realized by adjusting the optical path length between EOMs. The available higher-order harmonic number may be limited by the fiber noise of the delay line. For example, fiber noise scales with n² in power spectrum density in the frequency domain, where n is the harmonic number.

An amplifier downstream of the phase modulator 206 is further implemented to amplify the power of the cw laser 204. The amplifier can comprise an erbium (Er) fiber amplifier (EDFA). The example arrangement of FIG. 3A includes an unbalanced interferometer having two arms (branches) 214a, 214b of non-equal length. In at least one embodiment the interferometer includes at least one input port and two output ports coupled by fiber optic couplers OC1 and OC2, 212a, 212b, respectively. The amplified light from the amplifier is received and split in two branches 214a, 214b by the first optical coupler OC1, 212a. In the upper branch 214b shown in FIG. 3A, the light is frequency shifted by another modulator 224, such as an acousto-optic modulator (AOM). A synthesizer 240, which may be external to the interferometer, is provided to generate the acoustic frequencies for the AOM 224. In the lower branch 214a, the light is time-delayed by a long optical delay line 210, which in this example contains a long length of optical fiber, for example a length of 100 m to 10 km. The optical delay line further contains a short section of adjustable (e.g., tunable) short optical delay, comprising for example a fiber stretcher or an adjustable optical stage.

One issue with typical frequency shifting AOMs is the limited extinction ratio of non-shifted light in the output of the frequency shifted arm. Typical extinction ratios can be as high as −60 dB, e.g., the output power in the non-shifted output can be as high as 10⁻⁴% of the shifted output power. Though this is a small number, it can be detrimental in the presence of interference between the non-shifted light and another signal source, which depends on the signal amplitude and not the signal power. To avoid this type of detrimental interference between residual non-frequency shifted light transmitted by the AOM in the upper branch 214b and light from lower branch 214a, an additional AOM can be installed in the lower branch 214a (not shown). The second AOM can for example frequency shift the light in the opposite direction of the first AOM. As a result the extinction ratio of non-frequency shifted light to frequency shifted light can be approximately doubled to around −120 dB. The use of two AOMs to improve the extinction ratio of AOMs is generally applicable also to other applications of frequency shifting AOMs.

The light from the two branches 214a, 214b of the interferometer is recombined by the second optical coupler (OC2) 212b. Two narrow bandwidth optical bandpass filters (BPFs) are inserted into both output arms of the second optical coupler to pass at least one optical sideband generated by the EOM. To obtain any sensitivity to phase noise, the two bandpass filters can be selected to pass sidebands of different order, e.g., the 0th-order sideband (the cw laser itself) and the +1st-order sideband, or the −1st-order and +1st-order sidebands. Other combinations are also possible, e.g., the 0th-order sideband and the +n-th-order sideband (or the −n-th-order sideband) or the −n-th-order and +n-th-order sidebands. The filtered outputs (passed by the bandpass filters) are further directed to two separate photodetectors (PD), which may comprise photodiodes, and are electronically filtered at the frequency of the AOM, based on the selection of appropriate RF filters. Additional RF or optical amplifiers can further be implemented upstream of the photodetectors.

At the photodetectors (PDs), two self-heterodyne signals are detected. The two signals at the modulation frequency of the AOM are mixed by an RF mixer 220, which may be operated at or near quadrature phase difference (e.g., a phase difference of)90°. Amplifiers (amp) can be used upstream of the mixer. Operation in quadrature can be ensured by the variable short tunable optical delay. If necessary, a phase locked loop (PLL) 310 can be employed to ensure operation at the quadrature point for very long time.

At the mixer 220, any fiber noise is down-converted from the optical frequency domain to the DUT frequency domain, whereas the frequency or phase noise from the cw laser and the frequency or phase noise from the AOM are cancelled, producing a direct current (DC) signal containing the DUT phase noise and the fiber noise down-converted to the DUT frequency, f_{DUT}. For purpose of explanation and without intending to be bound or limited by theory, for the 0-th sideband, the signal can be expressed as

DC+cos(2πf_{AO}t+2πf_{c}τ(t)+φ_{cw}(t)−φ_{cw}(t−τ)+φ_{AO}(t)).

For the 1-st sideband, the signal can be expressed as

DC−cos(2πf_{AO}t+2π(f_{c}+f_{DUT})τ(t)+φ_{cw}(t)−φ_{cw}(t−τ)+φ_{AO}(t)+φ_{DUT}(t)−φ_{DUT}(t−τ)).

After the mixer, the signal can be expressed as

cos(2πf_{DUT}τ(t)+φ_{DUT}(t)−φ_{DUT}(t−τ)).

In the above equations, f_{AO} is the AOM frequency, f_{c} is the optical frequency, φ_{cw} (t) is phase noise of the cw laser, τ is a delay, φ_{AO} (t) is the phase noise of the AOM, φ_{DUT}(t) is the phase noise of the DUT, and τ(t) is a time-dependent delay, e.g., fiber noise.

To reduce fiber noise or residual phase noise from the cw laser as detected after the mixer 220, an additional phase locked loop 310b can be implemented. An example of such an implementation is shown in FIG. 3B. The signal after one of the PDs (e.g., the top PD in FIG. 3B) is mixed with the RF drive signal for the AOM 224 in the mixer 222, producing a signal down-converted to DC, which contains the relevant phase information related to fiber noise at optical frequencies and delayed cw phase noise such as

2πf_{c}τ(t)+φ_{cw}(t)−φ_{cw}(t−τ).

The above phase information can be used as an error signal and input to a phase locked loop (PLL2) 310b acting on a modulator, for example the modulation input of the cw laser 204 at the front of the system. The PLL2 reduces fiber noise, if fiber noise is larger than the phase noise of the cw laser. On the other hand, the PLL2 reduces the phase noise of the cw laser, if it is larger than the fiber noise. Provided, a low noise cw fiber laser is implemented, a large suppression of fiber noise can be achieved.

The output signal from the mixer 220, as already described by Eq. (1), is directed to an FFT signal analyzer 230, resulting in the DUT phase noise modified by the delay transfer function |H(jf)|², as described with reference to Eq. (1). The DUT phase noise is obtained by dividing the output of the FFT analyzer with the delay transfer function. The path lengths along the two branches between the second output coupler OC2 212b and the mixer 220 preferably should be optimized empirically for improved or optimal cw laser noise suppression. Also, the phase difference of the two signals injected to the mixer 220 may differ from the quadrature point for optimum noise suppression and can be optimized empirically.

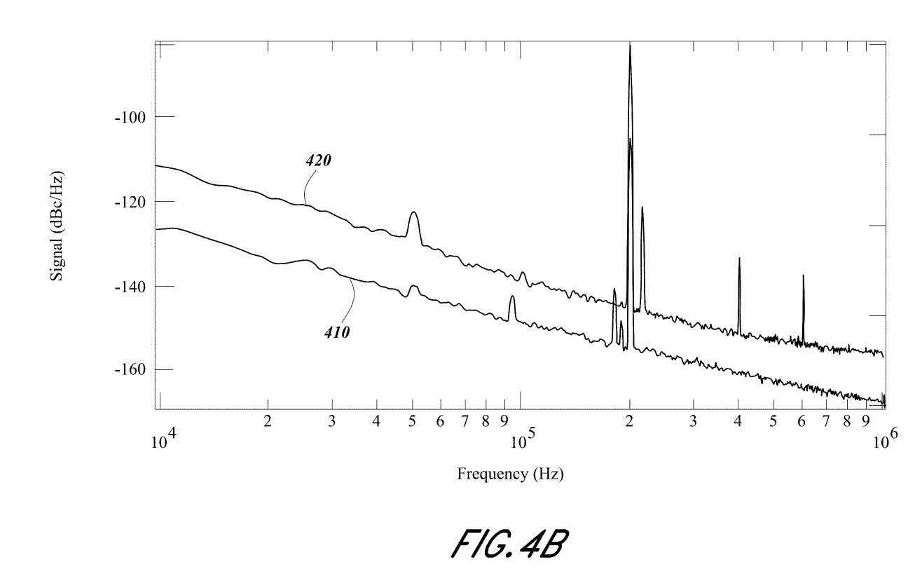

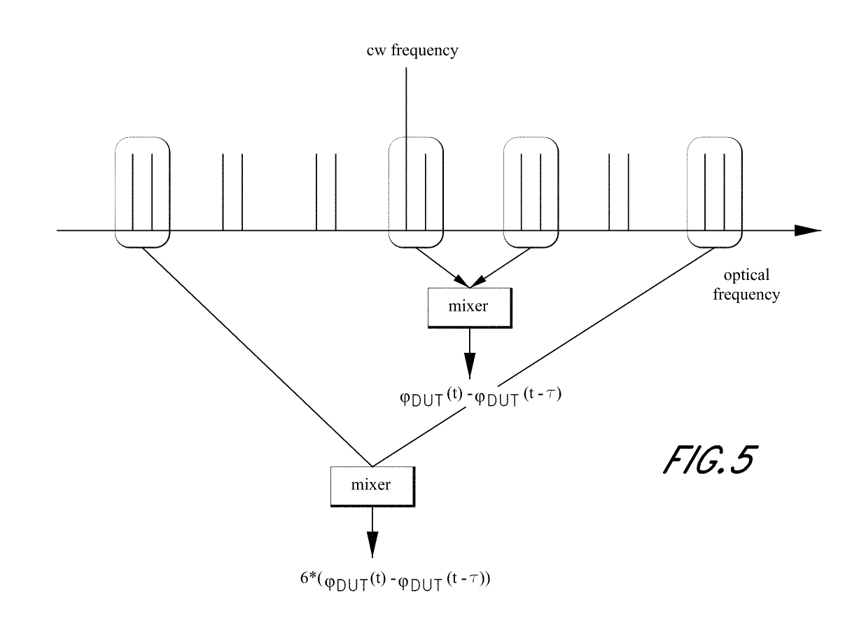

FIGS. 4A and 4B show examples of phase noise measurements of a low noise 10 GHz dielectric resonator oscillator (DRO) used as the DUT 102. Here a fiber optic delay line of about 100 m length was used. FIG. 4A shows the obtained signal at the signal analyzer 230, whereas the top curve 420 in FIG. 4B shows the obtained single sideband phase noise of the DRO by dividing with the delay transfer function, |H_{φ}(jf)|²=Csin²(πf τ). In FIG. 4B, the bottom curve 410 corresponds to the estimated noise floor of the system. The noise floor is affected by various processes, such as imperfect noise cancellation at the mixer or residual noise of the cw laser. Ultimately, the noise floor can be limited by shot noise at the photodetectors as well as noise arising from the long fiber delay line. However, delay lines up to lengths of 10 km and even more can still be effectively used.

In some implementations, the sensitivity to detectable phase noise of the system can be improved by the use of higher-order sidebands generated by the EOM, which can in turn be selected by the optical bandpass filters. For example, when the passed wavelengths are set to the 1st-order sideband, the detected signal contains the phase noise of the DUT minus the time delayed phase noise of the DUT. When the passed wavelengths of the bandpass filters are set to the +3rd and −3rd order sidebands, the detected signal contains: 6*[(phase noise of DUT)—(time delayed phase noise of DUT)], e.g., the phase noise sensitivity improves by a factor of 6. Generally, when the +n-th and −n-th order sidebands of the comb are used, the detected signal contains 2n*[(phase noise of DUT)—(time delayed phase noise of DUT)]. In the power spectral density in the frequency domain, use of +n-th and −n-th order sidebands enhances the sensitivity by a factor of (2n)², which is 20*log(2n) in dB (see also the discussion of Eq. (1)). Using +n-th and −n-th higher harmonics enhances not only the sensitivity, but also makes the system less sensitive to amplitude noise of the cw laser and amplitude noise of the RF modulation frequency for the AOM. The reduction in amplitude sensitivity also scales with 20*log(2n). In various implementations, the comb sideband (or mode or harmonic) number n can be 0 or a positive integer: 1, 2, 3, 4, 5, 6, up to 10, up to 20, up to 30, up to 50, up to 100, up to 250, or more. In various implementations, higher order sidebands have n≥3, n≥5, n≥10, n≥20, or more. In various implementations, the phase noise analyzer 104 or RF generator 100 can utilize modes with n in a range from 0 to 10, 0 to 20, 0 to 30, 0 to 100, or some other range. In various embodiments, the mode number n of the sidebands used can be less than 10, less than 20, less than 30, less than 50, or less than 100.

The principle of using higher order sideband for the enhancement of phase noise sensitivity is further explained with respect to FIG. 5 in the frequency domain. Here the frequency of the cw laser as well as the first six generated sideband, e.g. the first 3 positive and three negative sidebands are shown. Also the small frequency shift imparted by the AOM is displayed. Mixing the 1st order sideband and the cw laser (n=0) produces an output proportional to φ_{DUT} (t)−φ_{DUT} (t−τ), where φ_{DUT} (t) represents the phase noise of the DUT and φ_{DUT} (t−τ) represents the phase noise delayed by τ, where τ is the group delay imparted by the optical delay line. Mixing, for example, the −3rd and the +3rd order sidebands produces an output proportional to 6 [φ_{DUT} (t)−φ_{DUT} (t−τ)].

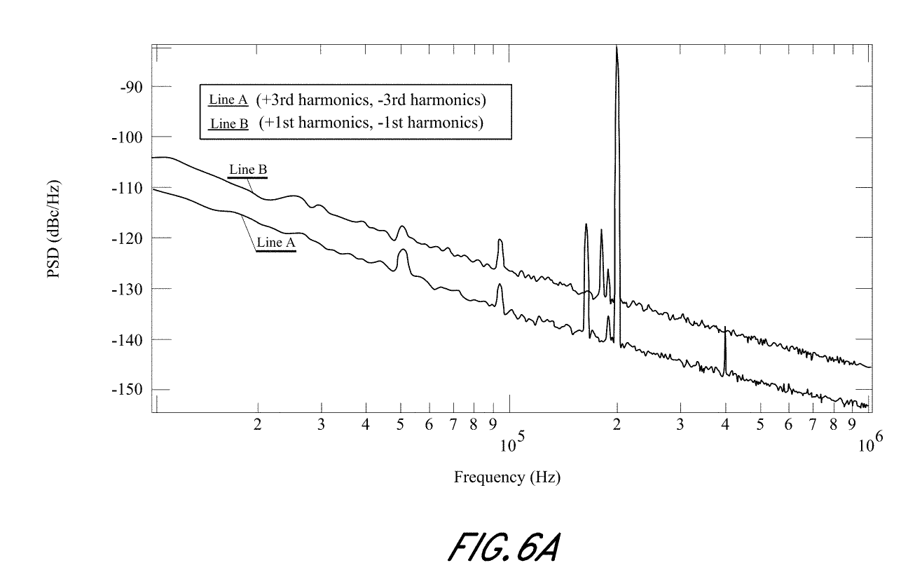

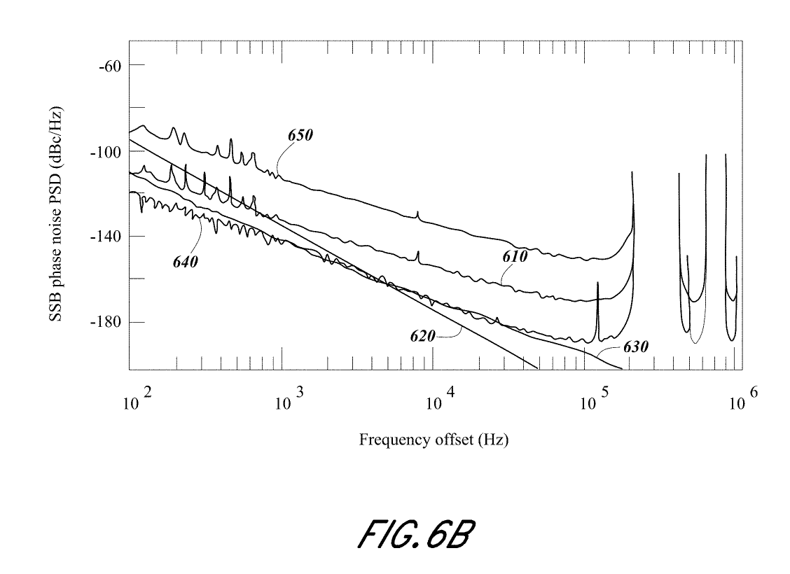

FIG. 6A shows an example of the enhancement of the sensitivity obtained via the use of higher order sidebands, where the use of the ±1st order sidebands (upper curve, Line B) and the ±3rd order sidebands (lower curve, Line A) is compared. When using the +3rd and −3rd order harmonics, the sensitivity is improved by about 9.5 dB (=20*log(6)−20*log(2)), as expected.

Generally, a variety of noise sources limit the achievable sensitivity of some embodiments of the phase noise analyzer. The influence of background noise (e.g., electronic or optical), fiber noise, cw laser noise, and intensity noise before photodetection on phase noise sensitivity were separately analyzed and are shown in FIG. 6B. Curves 610, 620, 630, and 640, respectively, are sensitivity limits from background noise, fiber noise, cw laser noise, and intensity noise before PDs for the use of +/−10th order sidebands, when using a fiber delay of 1 km. A curve 650 in FIG. 6B shows sensitivity limits from background noise for the use of +/−1st order sidebands. The sensitivity improvement using n=10 order sidebands compared to n=1 order sidebands is 20 dB=20*log(10)−20*log(1), as expected. Using pairs (±) of sidebands with n greater than 10 should enable even higher sensitivity (e.g., n up to 20, up to 30, up to 50, up to 100, or more).

Note that the sensitivity limit due to fiber noise (curve 620) can be further lowered by enclosing the fiber in a chamber which is isolated against mechanical, acoustic and thermal noise. Enclosure of the fiber in a vacuum chamber is also possible to lower the influence of fiber noise.

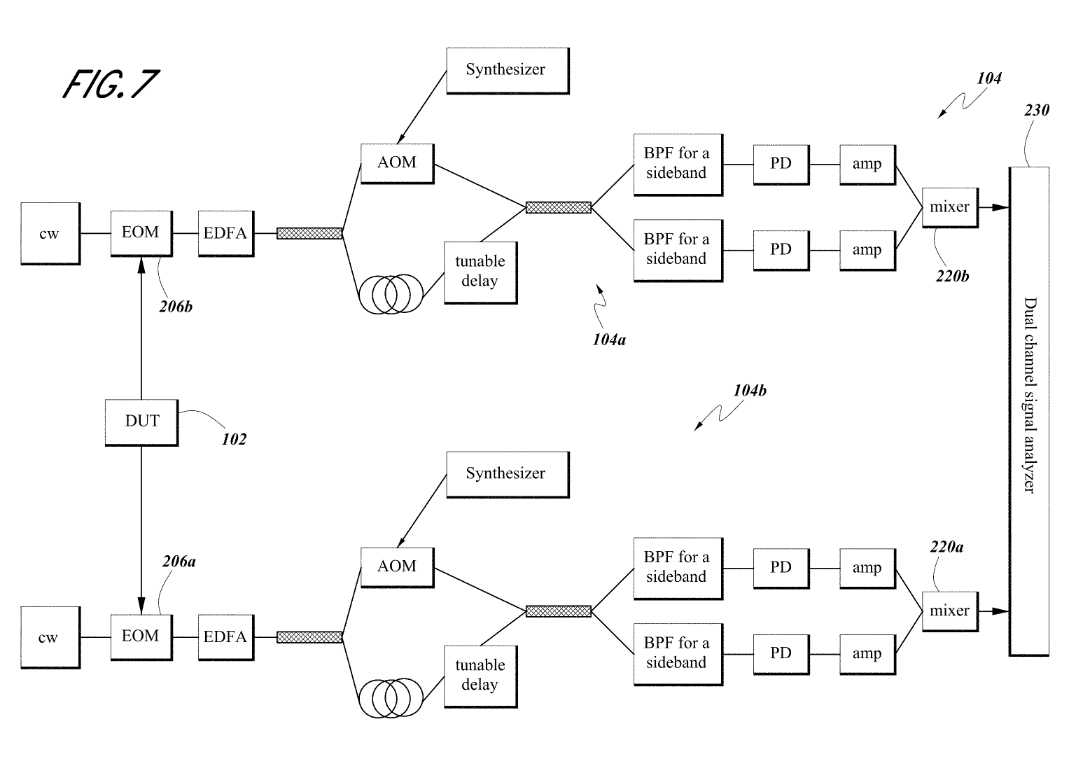

By making two independent systems, the cross correlation method can optionally be used to further enhance the sensitivity. An example implementation of the cross correlation method is shown in the phase noise analyzer 104 of FIG. 7. The system contains two independent phase noise analyzer systems 104a and 104b that are generally similar to those already discussed with respect to FIGS. 3A and 3B. In FIG. 7, only the DUT 102 is common for the two systems, where the DUT modulates the EOMs 206a, 206b embedded in both systems. The two detected signals after the mixers 220a, 220b are analyzed and averaged by a dual-channel FFT signal analyzer 230, which cancels out the uncorrelated noise by a factor of 5*log(N) in power spectral density (PSD), where N is the number of averages. Another example of cross correlation that can be used is disclosed in U.S. Pat. No. 8,155,913, ‘Photonic-Based Cross-Correlation Homodyne Detection with Low Phase Noise’ to D. Eliyahu et al. (the '913 patent).

One possible feature of the certain embodiments of the phase noise analyzer 104, for example as shown in FIGS. 3A, 3B and 7, is that the transfer function goes to zero at certain singularities corresponding to offset frequencies f₀=1/mτ, where m is an integer. At the singularities, the phase noise measurement method as described herein may have limited validity. Moreover, for small offset frequencies, the phase noise sensitivity increases proportional to τ², e.g., to obtain high phase noise sensitivity at small offset frequencies, it may be advantageous to use relatively long delay lines, which in turn reduces the frequency of the first singularity and the measurement range. For example, from the delay transfer function a 100 m delay line optimizes the phase noise sensitivity at 1 MHz, a 1000 m delay line optimizes the phase noise sensitivity at 100 kHz, and a 10,000 m delay line optimizes the phase noise sensitivity at 10 kHz.

This same feature is also encountered for conventional homodyne phase noise analyzers as discussed in the '913 patent and can be avoided by implementing a phase noise analyzer with several delay lines and concatenating the results from the different delay lines appropriately, e.g., by using long delay lines for the phase noise at small offset frequencies and using short delay lines to improve the measurement range at high offset frequencies. Optical delay lines of different lengths can for example be incorporated and selected into the set-ups shown in FIGS. 3A, 3B, and 7 using appropriate switches inserted at the beginning and the end of the delay lines 210 that switch between different delay lines as desired. Therefore, to obtain a frequency range for high sensitivity phase noise analysis from approximately 10 Hz to 1 MHz, for example delay line lengths of 10,000 m and 100 m can be implemented, or 10,000 m, 1000 m and 100 m. Other fiber delay line lengths in a range from ≈100 m to ≈10 km can also be used. Delay line lengths much greater than 10,000 m become increasingly ineffective, as the fiber noise itself limits the sensitivity of the phase noise analyzer. A delay line length of 10 km can be used for measurements down to ≈10 Hz, though phase noise sensitivity is reduced by almost a factor of 60 dB compared to the maximum sensitivity at 10 kHz for that delay line length. Accordingly, the delay line 220 can comprise a plurality (e.g., 2, 3, 4, or more) of delay lines with different delay line lengths.

Increasing or optimizing DUT power (for example by an attenuator) makes the system more insensitive to amplitude modulation (AM) noise of the DUT. This can for example be experimentally verified by adding a small AM component to the DUT and observing the AM reduction in the phase noise spectrum as a function of DUT power.

Embodiments of the phase noise analyzer 104 further allow the effective use of relatively large cw powers from the cw laser 204, as for example shown in FIGS. 3A or 3B or amplified by the Er amplifier located down-stream of the cw laser 204 without onset of noise due to stimulated light scattering. The reason for the relative insensitivity to Brillouin scattering is that the electro-optic modulator greatly broadens the bandwidth of the signal transmitted through the fiber lengths compared to the bandwidth of the cw laser. Experimental measurements showed that for a 1 km fiber length, a signal after the Er amplifier of around 100 mW did not lead to any visible onset of noise due to stimulated Brillouin scattering. This means that for a 10 km fiber length, a power level of still around 10 mW is possible. With the use of large or hollow core fibers, the nonlinear thresholds could even be further increased.

The use of hollow core fibers allows a significant reduction of fiber noise of certain embodiments of the phase noise analyzer 104. For example, the reduced coupling of thermal to group delay variations in hollow core fibers can be effective in limiting fiber induced phase variations at the coupler OC2. With hollow core fibers with a loss of <10 dB/km, as for example obtainable from commercially available photonic bandgap or photonic crystal fibers, the use of a hollow core fiber up to a length of around a few km can be effective to reach a very low noise floor for phase noise analysis.

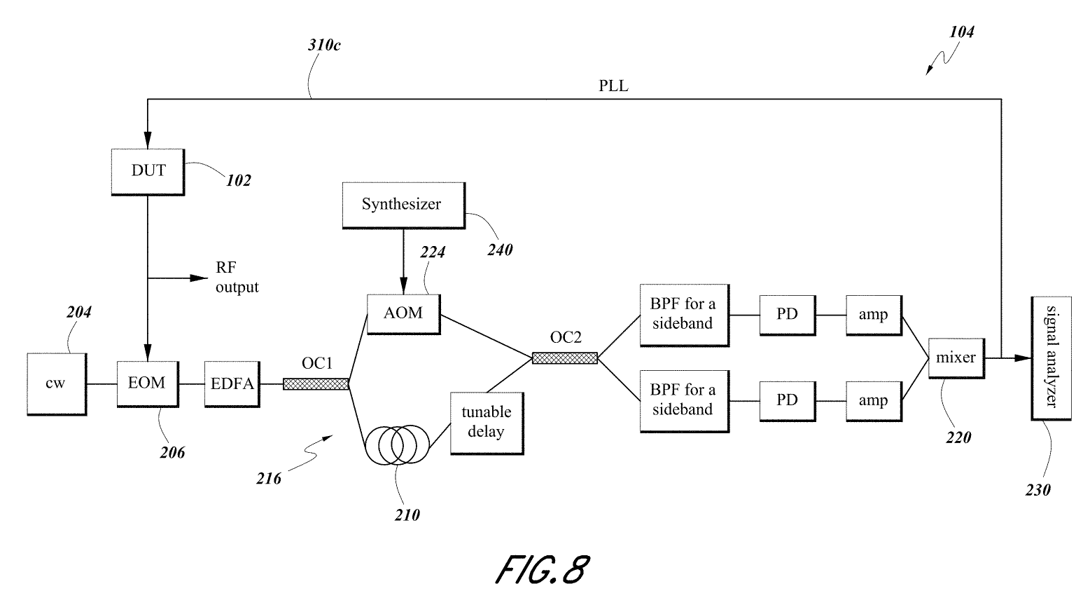

The example phase noise analyzers as shown in FIGS. 3A or 3B can also be used for phase noise reduction of the DUT as already described with reference to FIG. 1; an example implementation is shown in FIG. 8. The system can be based on a phase noise analyzer 104, which can be very similar to the system shown in FIGS. 3A or 3B, but for the addition of an additional phase locked loop 310c, which uses the output of the mixer 220 as an error signal and feeds back a control signal to the DUT 102 (shown in FIG. 8) or the RF frequency synthesizer 240 to satisfy the following equation, 2πf_{RF}τ+φ_{RF} (t)−φ_{RF} (t−τ)=(2m+1)π/2, where m is an integer. Here, f_{RF} and φ_{RF} (t) are the RF frequency and the phase noise to be stabilized, respectively. A low phase noise RF signal can then be extracted between the DUT 102 and the EOM 206 with an appropriate RF splitter. As explained already with respect to FIG. 3A, to suppress the phase noise of the cw laser 204 or the phase noise imparted by the fiber delay line 210, another PLL can also be implemented using the output of one of the photodiodes at the AOM frequency and down-converting it to DC via mixing with the AOM drive frequency (for simplicity, this is not separately shown here). As explained already with respect to FIG. 5, to enhance the phase noise sensitivity, higher order sidebands can be implemented.

To achieve an increased or optimum suppression in the phase noise imparted by the fiber delay line, a low noise cw laser can be selected. For improved performance a low noise cw laser derived from an optical frequency reference can be effectively used in this scheme. The end result is that the measured phase noise of the DUT is suppressed with the optical cw reference laser or the imbalanced fiber delay line acting as the frequency reference. Because the fiber noise at optical frequencies is referenced to a stable cw laser and the noise of the RF synthesizer is referenced to the fiber noise in the RF domain, a large suppression of RF phase noise of the synthesizer can be obtained.

A hollow core fiber can also be used to improve the system performance, as already described with respect to FIGS. 3a and 3b. Hollow core, photonic bandgap, or photonic crystal fibers can be used inside a delay line (based on the fiber coil 210) to reduce the fiber noise of the delay line. A hollow core fiber can itself be used as a frequency reference to reduce the phase or frequency noise of the cw laser 204. Sub-Hertz cw laser linewidths and a frequency stability less than 1×10⁻¹⁴ in 1 sec have for example been demonstrated when locking a cw laser to a conventional fiber delay line, as discussed in J. Dong et al., ‘Subhertz linewidth laser by locking to a fiber delay line’, Applied Optics, 54, pp. 1152 (2015). When using a fiber delay line based on hollow core fiber, a frequency stability of <1×10⁻¹⁵ is possible.

The theoretically achievable phase noise of the DUT 102, φ_{RF}, can in fact reach

[φ_{RF}(f)]²=(1/R²)[φ_{cw}(f)]²,

where R is the frequency ratio R=(optical carrier frequency)/(RF frequency) and φ_{cw} is the phase noise of the cw reference laser. In practice the phase noise of the DUT is limited by a variety of other factors, such as the limited gain of the PLLs, the latency within the PLLs, etc.

The low noise RF generation scheme as discussed with respect to FIG. 8 further allows for tunable, but discrete RF frequency generation, via measurement and suppression of phase noise via a phase noise analyzer. The RF tuning speed and range may be constrained by the tuning speed and tuning range of the RF. The possible frequencies of the generated RF are given by [π/(4τ)]×(2m+1), where m is determined by

π/2×(2m+1)−2πf_{DUT}τ=ε,

where ε is a small number [e.g., much smaller (e.g., by a factor of 1/5, 1/10, 1/20, 1/100, or less.) than individual terms on the left hand side of this equation]. For continuous tuning, t can be tuned for example by changing the delay fiber length via an appropriate temperature control. Other methods for fiber delay length tuning can also be implemented. In FIG. 8 the phase noise suppression of a DUT (such as a DRO) is disclosed as a way to achieve an ultra-low phase noise microwave output.

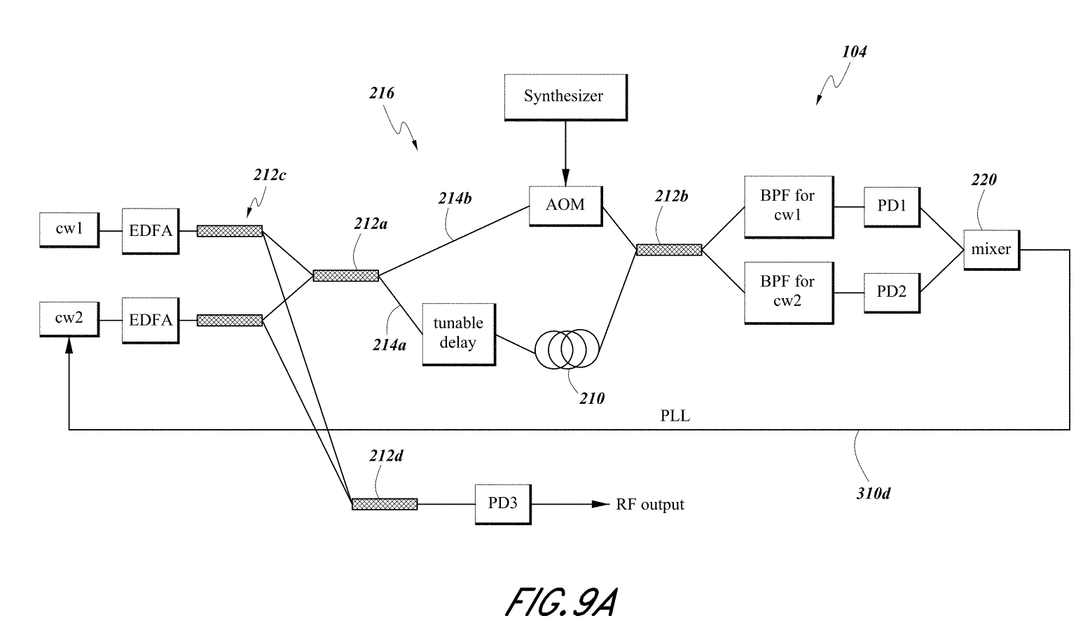

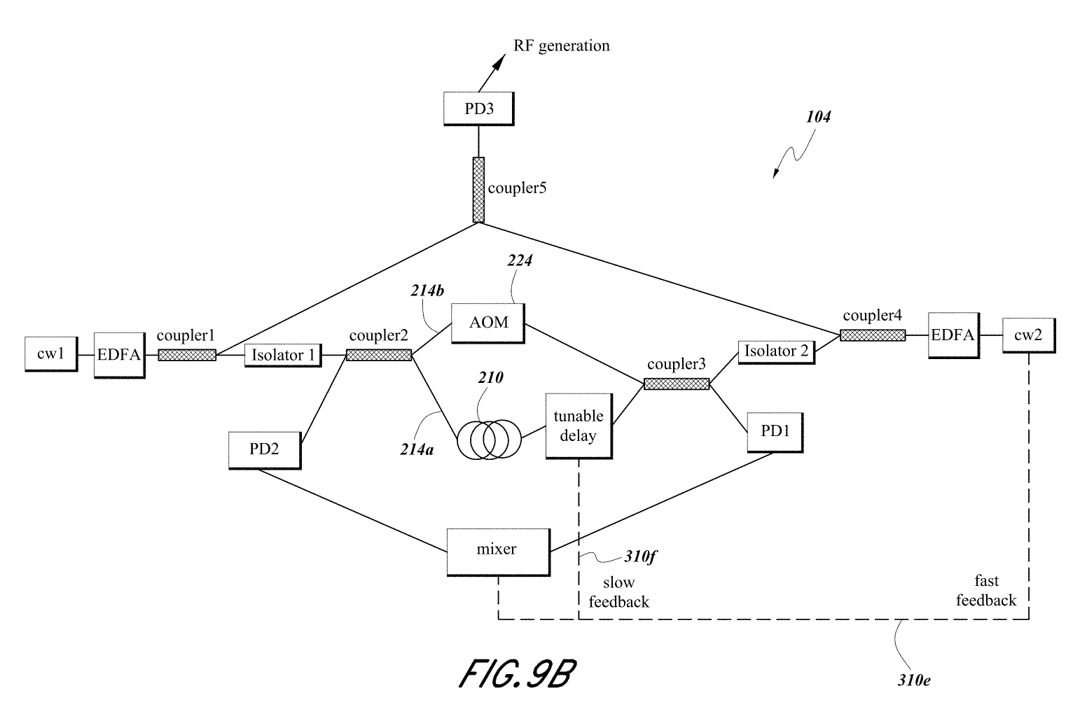

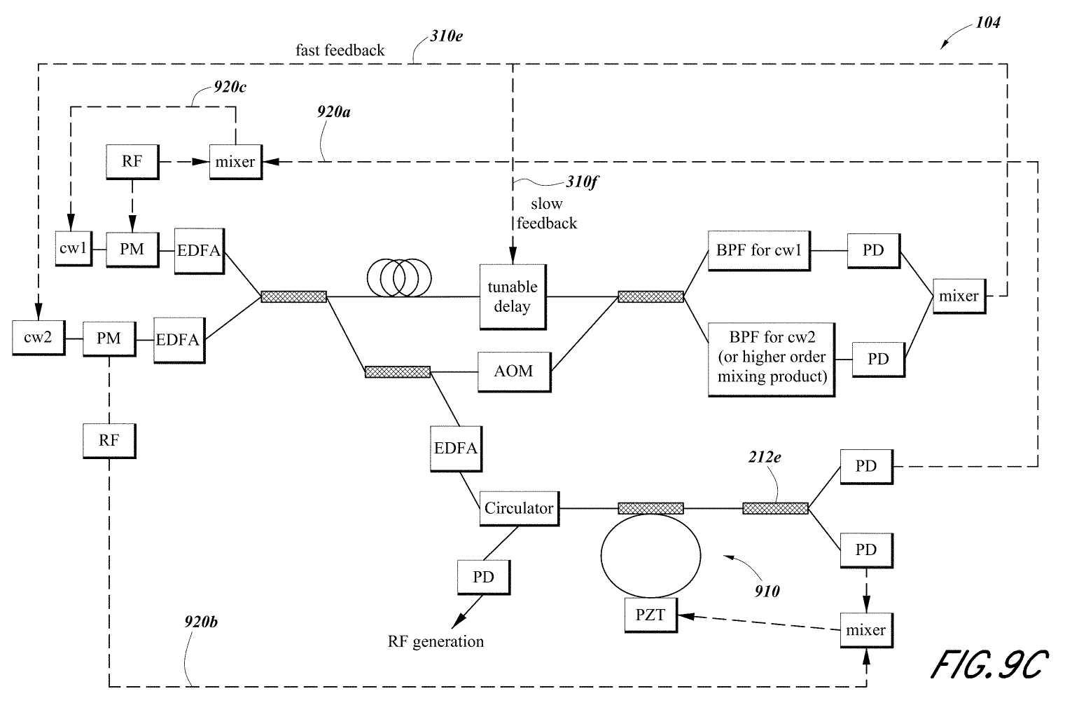

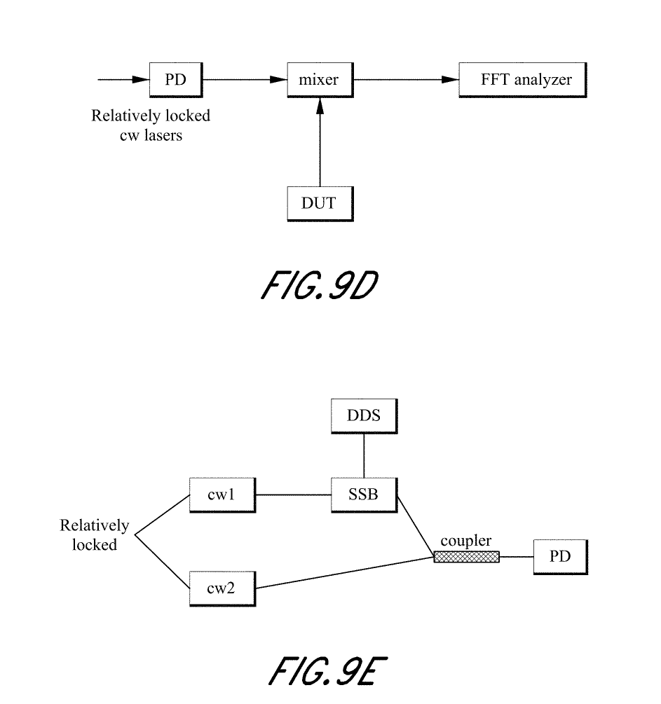

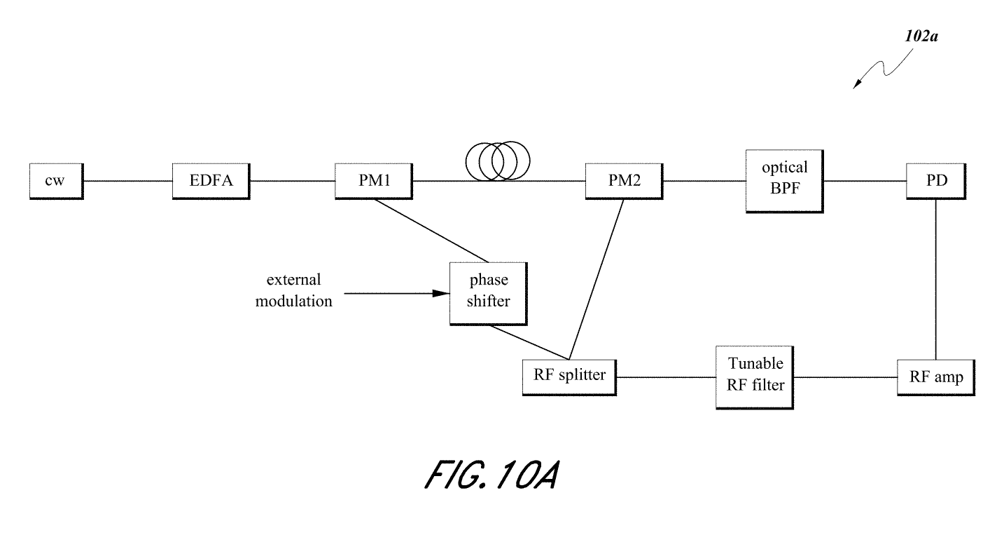

The phase noise suppression system as shown in FIGS. 3A and 3B, can also be used to phase lock two cw lasers with different optical frequencies, which enables low phase noise high frequency generation by detection of the beat signals between two cw lasers. An example implementation of such a system 104 is shown in FIG. 9A. As described previously, the system performance can also be improved via the use of hollow core fibers in the fiber delay line 210. Two cw lasers (cw1 and cw2) with optical frequencies f_{cw1} and f_{cw2}, respectively, are combined by a four-port coupler located downstream of the two cw lasers (and optional amplifiers such as EDFA). One output port of the coupler traverses an arm 214b comprising an AOM, and the other traverses an arm 214a comprising a long optical fiber delay line 210. The two signals are subsequently recombined with a second optical coupler 212b. After the 2nd coupler, two optical bandpass filters are installed for each port. The passband for the upper port is set at f_{cw1}, and for the lower port it is set at f_{cw2}. The light transmitted by the optical bandpass filters is detected with two down-stream photo detectors, the output of which is subsequently mixed in an RF mixer 220.

The RF mixer 220 generates a signal, which can be expressed as

cos[2π(f_{cw1} −f_{cw2})τ(t)+φ_{cw}(t)−φ_{cw1} (t−τ)−(φ_{cw2}(t)−φ_{cw2}(t−τ))], (2)

where φ_{cwk} (t) is the phase noise of the cw laser k (with k=1 or 2). By implementing a PLL 310d for feeding back the output of the RF mixer 220 to a modulator, for example, the modulation input for cw laser 2, the PLL 310d sets the argument of the cosine function in Eq. (2) to an odd (2m+1) multiple of π/2. In other words, the frequency separation of the two cw lasers is set to [1/(4τ)]×(2m+1) and the phase noise of cw laser 2 is set to that of cw laser 1.

As a result of this operation the phase noise of cw laser 1 is coherently transferred to cw laser 2 and a low noise carrier with frequency ΔF=f_{cw1} −f_{cw2} can be generated by detection of the beat signal of the two cw lasers on a photo-detector. For frequency tunability, a tunable delay can be installed in the fiber delay line 210 (e.g., as shown in FIG. 3A).

As shown in FIG. 9A, such a low noise beat signal can be detected with a third photodiode PD3, which receives inputs from lasers cw1 and cw2 via appropriate optical coupler(s) 212d inserted downstream of the lasers cw1 and cw2.

The RF generation scheme as discussed with respect to FIG. 9A also allows for rapidly tunable, but discrete microwave generation in the range from a GHz to several THz, limited by the detection bandwidth of the photodetector PD3. In analogy to the discussion above, the frequency of the generated RF is given by f_{cw1} −f_{cw2}=[π/(4τ)]×(2m+1), where the integer m is determined by

π/2×(2m+1)−2π(f_{cw1} −f_{cw2})τ=ε,

and where ε is a small number (as described above). For continuous tuning, τ can be tuned by changing the delay fiber length via an appropriate temperature control, though other methods for fiber length tuning can also be implemented.

Similar to the discussion with respect to FIG. 2B, the sensitivity of the phase noise analyzer can be enhanced by the use of higher harmonics of the fundamental RF frequency under test. In the example from FIG. 9A, higher harmonics of the fundamental beat frequency between the two cw lasers cw1 and cw2 can be generated in appropriate highly nonlinear fibers inserted upstream of the coupler 212a. For example, to generate higher harmonics, the two cw lasers can be combined in a coupler, followed by a length of highly nonlinear fiber. Coupler 212a then directs the broadened optical spectrum to the phase noise analyzer 104, and the bandpass filters select higher harmonics. Cascading of sections of highly nonlinear fiber, optionally with inserted pulse compression stages, can also be implemented. Highly nonlinear waveguides can also be used for the same purpose. A further reduction of the phase noise between the two cw lasers by 10 or 20 dB and even more can so be obtained.

Two cw lasers have also been locked to each other via an interferometer or a fiber delay line, as for example discussed in U.S. Pat. No. 8,331,409. However such systems did not at least implement a mixer. The use of a mixer allows for direct locking of the two cw lasers to each other without separately locking between the fiber interferometer and each individual cw laser, as implemented in the '409 patent. Moreover, in the '409 patent, no acousto-optic modulator to shift the beat signal outside the range of 1/f noise was used, further degrading the possible performance.

As shown in the system 104 schematically illustrated in FIG. 9B, a bidirectional setup does not require optical BPFs for differentiation of the interference signals related to the two cw lasers, cw1 and cw2. In this setup, the two cw lasers propagate along the fiber delay line from opposite directions. Because of counter propagation, the photodetector PD1 only detects the phase noise of the laser cwl. Isolator 2 is inserted to prevent the injection of light from cw1 to cw2. On the other hand, the photodetector PD2 only detects the phase noise of the laser cw2. Isolator 1 is inserted to prevent the injection of light from cw 2 to cw 1. By mixing two signals from the two photodetectors PD1 and PD2, the same expression for the signal as previously shown in Eq. (2) is obtained. As shown in FIG. 9B, this signal is fed back via feedback loops 310e, 310f to appropriate modulators (e.g. the laser cw2 and/or the tunable delay, where cw2 can typically be modulated more rapidly than the tunable delay line), resulting in relative phase noise reduction of the two cw lasers. For RF generation, a fraction of the outputs from the lasers cw1 and cw2 is taken out via couplers 1 and 4. Then, these two signals are interfered through coupler 5 and photo detected via photodetector PD3, generating RF.

As shown in the embodiment of the system 104 schematically illustrated in FIG. 9C, the phase noise of an RF source based on heterodyning of two cw lasers, as discussed with respect to FIG. 9B, can be further suppressed by using a dual frequency Brillouin cavity. The two cw lasers can be locked to each other via a fiber delay line and can be configured to pump one Brillouin cavity, resulting in reduced phase noise at the beat frequency of the two Brillouin signals. Locking of two independent cw lasers to a single fiber Brillouin cavity was previously described in U.S. Pat. No. 9,537,571 to Li et al. However, generation of millimeter (mm) wave signals via an appropriate photodetector was not considered; moreover no means of coupling one laser to the other in order to minimize the phase noise between the two cw lasers was introduced. Also, no means for mm wave tuning was described.

In the embodiment shown in FIG. 9C, a Brillouin cavity 910 (comprising a fiber ring towards the bottom of FIG. 9C generates two frequency-shifted tones at frequencies f_{cw1}-f_{Bri1} and f_{cw2}-f_{Bri2} in the direction opposite to the pumps. In FIG. 9C a Brillouin cavity 910 based on a fiber ring is shown, but any other Brillouin cavity can also be used. Brillouin cavities may comprise for example microresonators or spiral resonators. A circulator is installed before the Brillouin cavity to extract the two Brillouin tones. To generate the Brillouin tones, an amplifier, EDFA, is disposed before the circulator. By beating the two Brillouin tones at a photodetector, a low phase noise carrier at a frequency (f_{cw1}−f_{Bri1})−(f_{cw2}-f_{Bri2}) is generated.

The frequencies f_{cw1} and f_{cw2} have to be integer multiples of the free spectral range (FSR) of the Brillouin cavity (FSR_{Bri}). To keep this frequency relationship stable, two Pound Dreyer Hall locks (PDHs) for the two Brillouin cavity pump tones from cw1 and cw2 can be applied. To facilitate two PDHs, two phase modulators (PMs) are installed after cw1 and cw2, respectively. The PMs are modulated with different RF frequencies and the transmission from the Brillouin cavity is split in two at coupler 212e and photodetected. The outputs from the PDs are mixed with the RF signals, which drive the phase modulators. Because of the use of two different RF frequencies applied to the two PMs in this PDH arrangement, the error signals for the two cw pump tones for the Brillouin cavity are generated independently at each photodetector PD.

The error signal relating to the laser cw1 is fed back to cw1 and the error signal relating to the laser cw2 is fed back to a piezoelectric transducer (PZT) in the Brillouin cavity 910. Because of the presence of three feedback loops 910a, 910b, 910c in the PDH arrangement of FIG. 9C, the following equations need to be satisfied simultaneously:

$$\begin{matrix}{f}_{cw 1} = {nFSR}_{Bri} & ( 3 a ) \\ {mFSR}_{Bri} = {f}_{cw 2} & ( 3 b ) \\ {f}_{cw 1} - {f}_{cw 2} = \frac{1}{4 τ} \cdot ( 2 k + 1 ) & ( 3 c )\end{matrix}$$

In Eqs. (3a)-(3c), n, m, and k are integers and ti is the time delay along the fiber delay line. Because of these equations, the generated carrier frequency is the least common multiple (+offset) of 1/τ and FSR_{Bri}. For example the frequencies can be selected such that (n−m) FSR_{Bri}−(1/4τ)(2k+1)≈ε, where ε is a small number (e.g., much smaller than any of the terms on the right hand side of this relationship). This sets (n−m) and k for a given FSR_{Bri} and τ to obtain the required value for (n−m)'FSR_{Bri} to satisfy Eq. (3c) above. The free spectral range FSR_{Bri}, τ, or f_{cw1}, or f_{cw2} can then be tuned slightly.

In an alternative configuration (not separately shown), instead of using one Brillouin cavity 910, two Brillouin cavities can be used, where each cw laser can be locked to its own Brillouin cavity, enabling independent control of the Brillouin cavities. Appropriate phase modulators, circulators and amplifiers (e.g., EDFA) can be inserted, and the transmission from the Brillouin cavity can be photodetected analogously to the configuration shown in FIG. 9C to enable two independent PDH locks for locking the Brillouin cavities to the cw lasers. The PDH error signal can be fed back to either the cw lasers or the Brillouin cavities. Assuming for example that the laser cw1 is locked to a first Brillouin cavity, a Brillouin output of frequency f_{cw1}−f_{Bri1} can be extracted via a circulator. The Brillouin output has lower phase noise than cw1. In the same way, the laser cw2 can be locked to a second Brillouin cavity, generating another Brillouin output with frequency f_{cw2}−f_{Bri2}. The two Brillouin outputs can be propagated through an embodiment of the phase noise analyzer 104 as shown for example in FIG. 9A to generate an error signal to lock the two Brillouin outputs. The error signal can be fed back to a frequency shifter inserted upstream of the phase noise analyzer and one of the Brillouin outputs for further reduction of the relative phase noise between the two Brillouin outputs. As shown in FIG. 9A, a coupler can be installed in the system to extract the two Brillouin outputs and for generation of a low phase noise RF output with frequency of (f_{cw1}−f_{Bri1})−(f_{cw2}-f_{Bri2}).

Low phase noise microwave, millimeter wave, or THz frequency (micro-mm-THz) signals from the above-described systems can be used for phase noise analysis of a DUT. FIG. 9D schematically illustrates an embodiment of a system for generating low noise microwaves, which may be used for microwave spectral analysis. Low phase noise micro-mm-THz signals generated at a photodetector PD (or photo-mixer for mm—THz waves) using methods as for example described with respect to FIGS. 9A-9C can be mixed with a DUT via a mixer. The mixer can be a conventional RF mixer for microwaves, and a waveguide mixer for mm-THz signals. After the mixer, the down-converted signal can be analyzed with an FFT analyzer.

FIG. 9E schematically illustrates an embodiment of a system for the generation of low-noise frequency-modulated microwaves. As shown in FIG. 9E, two relatively locked cw lasers, cw1 and cw2, can also be used for chirped micro-mm wave generation. The two cw lasers can be locked with respect to each other by using for example any of the previously described methods. For simplicity, the arrangement for locking the two cw lasers is not shown here. One of the two cw lasers (cwl) is then electro-optically modulated by an optical modulator, for example a single sideband modulator (SSB) driven by a signal for example derived via the use of a direct digital synthesizer (DDS). The SSB generates an optical frequency (f_{SSB}) that can be expressed as,

f_{SSB}=f_{cw1}+f_{DDS(t)}.

In this equation, f_{cw1} is optical frequency of the laser cwl, and f_{DDS} is frequency of the DDS signal, f_{DDS}(t) can be linearly chirped, e.g., f_{DDS}(t)=(f_{range}/T)*t, where f_{range} is a chirped bandwidth, t is the time, and T is a cycle time. By interfering the laser cw1 with another cw laser, cw2, via an optical coupler, chirped micro-mm waves can be generated at an OEC such as the photodetector PD shown in FIG. 9E. The resulting frequency (f_{chirp}(t)) of the generated micro-mm waves can be expressed as

f_{chirp}(t)=(f_{cw1}−f_{cw2})+(f_{range}/T)*t.

By tuning the optical frequency f_{cw} of the laser cw2, the carrier frequency of the micro-mm waves can be changed. By changing the setting of the DDS, the chirp rate and the bandwidth can be changed.

The generation of precision chirped mm waves with carrier frequencies of hundreds of GHz can be generated using embodiments of the system shown in FIGS. 9D or 9E. Such signals can for example be useful for precision mm-wave imaging, as for example used in airport screening systems and other security applications.

### Alternative Microwave Oscillators

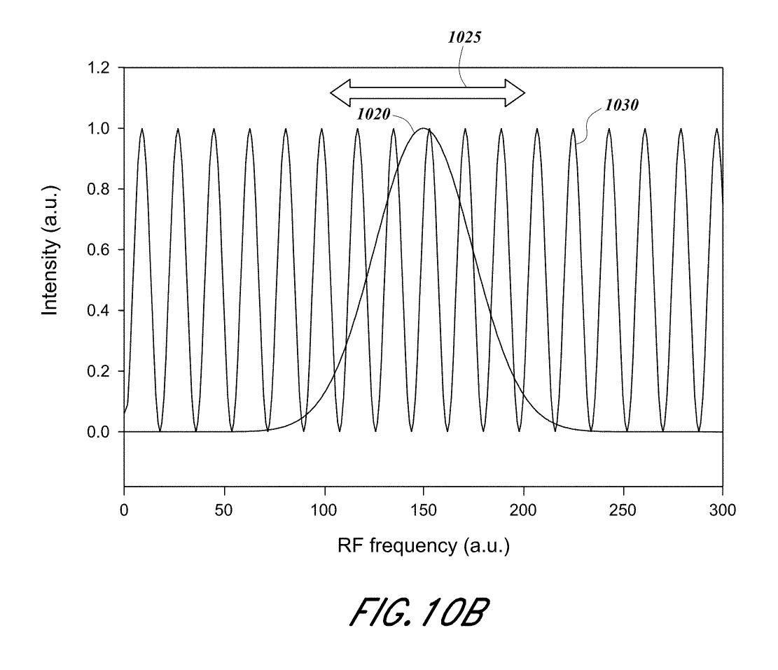

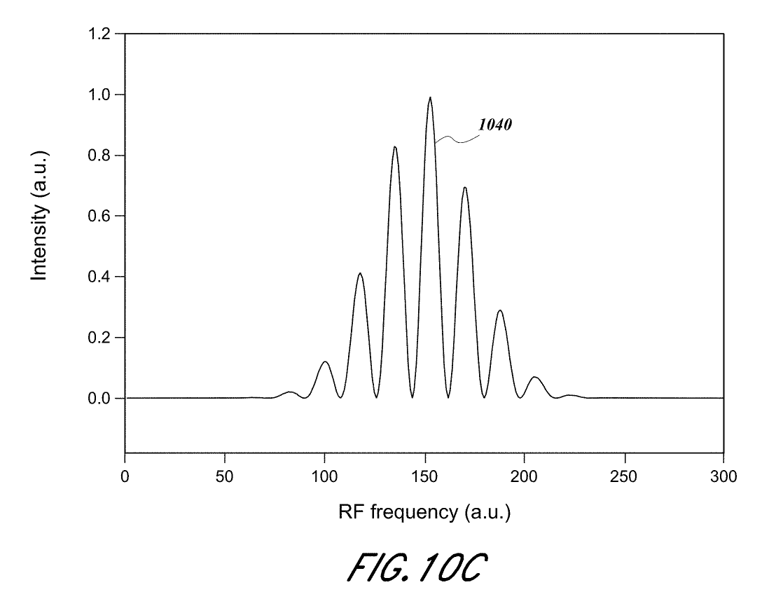

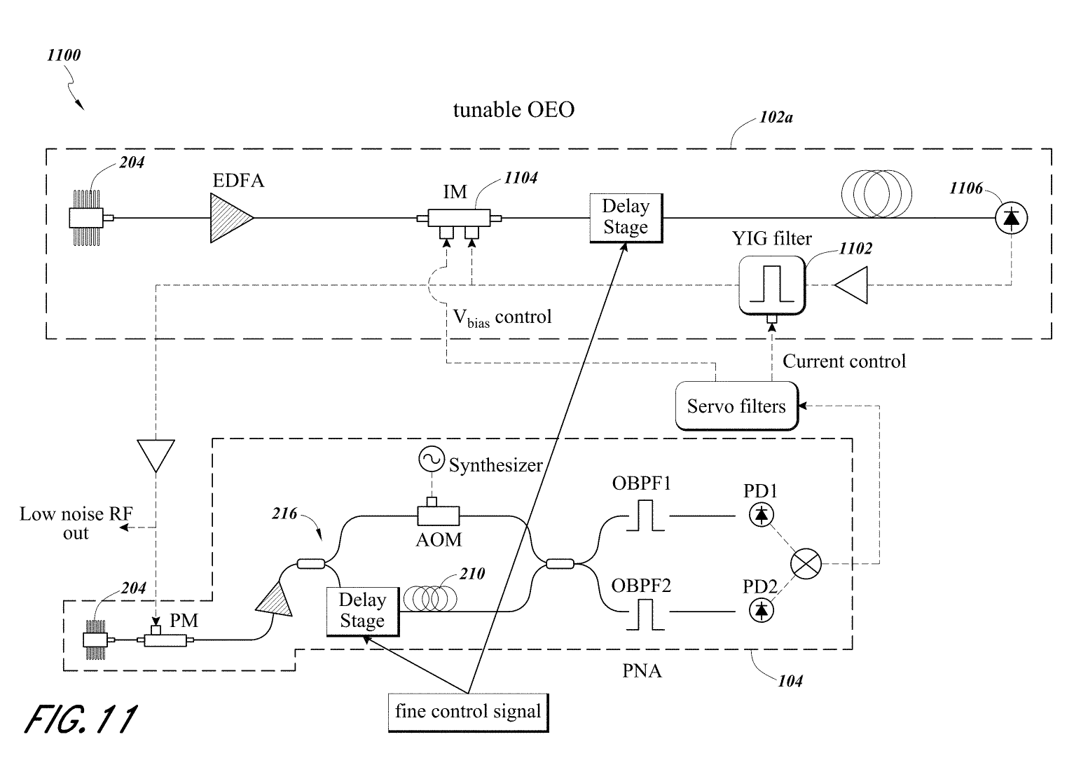

Various microwave oscillators can be used as the DUT 102 in the microwave generation systems 100 as introduced with respect to FIG. 1 and phase noise analyzers 104 described herein. As one example, a dielectric resonator oscillator (DROs) or a coupled resonator oscillator (CRO) can be used as the DUT. As another example of a DUT, the use of a low noise tunable opto-electronic oscillator (OEO) as a microwave oscillator 102 enables the generation of tunable ultra-low noise microwaves. OEO s can be implemented in different configurations (an example is described with reference to FIG. 10A). In order to control the phase noise of an OEO, an actuator typically can be incorporated into the OEO loop. An example of a suitable tunable OEO 102a is shown in FIG. 10A.

The example OEO 102a shown in FIG. 10A comprises a cw laser, two phase modulators, PM1 and PM2 (either or both of which may comprise EO PMs), a long fiber delay line, an optical filter (optical BPF), a photodetector (PD), an RF amplifier (RF amp), a tunable RF bandpass filter, an RF splitter, and a phase shifter, arranged in a circular (loop) fashion. For example a YIG (Yttrium Iron Garnet) filter can be used as a tunable RF bandpass filter. Such YIG filters can have a bandwidth of around 100 MHz and a tunable center frequency from 10 GHz to 20 GHz. Other tuning ranges are also possible. The tunable RF filter can be used to broadly tune the OEO frequency.

However, the bandwidth of the tunable RF filter may not be narrow enough to suppress sidemodes in the OEO (separated by the frequency spacing of the loop resonances). To suppress the sidemodes, a narrow RF bandpass filter can be realized in the optical domain by using the two PMs, PM1 and PM2, and the optical BPF. For this, an output from the tunable RF filter can be split by an RF splitter, and the split microwaves can be applied to the two phase modulators PM1 and PM2. The phase modulators are delayed along the loop and therefore exert a phase modulation onto the cw laser with a time delay t, corresponding to the time it takes for the light to propagate from PM1 to PM2.

Examples of transfer functions of the tunable bandpass RF (e.g., YIG) filter and the two PMs as a function of microwave frequency (in arbitrary units) are shown in FIG. 10B. The YIG filter produces a broadband (e.g., Gaussian-shaped) transfer function 1020, and the two PMs produce a sinusoidal transfer function 1030 with a frequency 1/τ. The combined filter response 1040 of both filters in the RF domain is shown in FIG. 10C, which is obtained by multiplying the two transfer functions 1020, 1030 shown in FIG. 10B. The OEO oscillates at the peak of the filter transmission curve. As the broadband RF filter is tuned over a tuning range illustrated by arrow 1025, the transmission peak of the broadband filter 1020 moves to different orders of the (stationary) sinusoidal filter 1030. Hence the OEO can be tuned in frequency in steps of 1/τ. To obtain continuous tuning, a dispersive delay line can optionally be incorporated between the two PMs, PM1 and PM2, which can further tune the position of the sinusoidal filter in conjunction with tuning of the cw laser frequency and the optical bandpass filter. Such an implementation is not separately shown.

Depending on the relative phase between the two PMs, the applied phase modulation to the cw laser is changed, resulting in changing the number of sidemodes of the cw laser. A function of the bandpass filter is to filter out the (coherently added) side-modes on one side of the cw laser (e.g., sidemodes with a frequency smaller or larger than the frequency of the cw laser) in order to convert the phase modulation induced by the phase modulators into amplitude modulation. The filtered sidemodes are then detected by a photodetector to convert the amplitude modulation to an RF signal. The optical bandpass filter may be omitted when using two amplitude modulators instead of two phase modulators or when replacing one of the two phase modulators with one amplitude modulator.

The bandwidth of the photonic based RF filter is of the order of 1/τ, which can be very narrow by inserting a long fiber between two PMs (e.g., to increase τ). In an example embodiment, τ is selected to be around 1 μs, producing a filter response with a bandwidth of around 1 MHz. In different embodiments, a filter bandwidth in the range from 100 kHz to 10 MHz can be implemented. Other ranges are also possible.

OEOs, such as the example 102a shown in FIG. 10A, can be designed to start from noise and can deliver ultra-low phase noise microwave outputs. To effectively use a phase noise analyzer for phase noise suppression, an error signal containing the output from the mixer 220 of a phase noise analyzer 104 can be fed back to the OEO 102a, for example to a phase shifter between PM1 and the RF splitter shown in FIG. 10A.

The inclusion of an actuator for phase noise reduction of an OEO was shown in the paper: ‘Highly Stable Wideband Microwave Extraction by Synchronizing Widely Tunable Optoelectronic Oscillator with Optical Frequency Comb’, December (2013) to D. Hou et al., where the bias control of the electro-optic modulator was used to receive an error signal. Thus, for example, higher order EO modes (e.g., n≥10,n≥20, n≥30, or more) can be used with the OEOs and phase noise analyzers described herein, which may lead to improved sensitivity. In addition to phase noise reduction in OEOs, embodiments of the phase noise analyzer 104 can also be implemented for phase noise reduction with other microwave oscillators, such as coupled OEOs (COEOs). Many other possibilities exist, which are not discussed here.

The achievable phase noise of the OEO 102a described with reference to FIG. 10A may, in some cases, be limited by the fiber noise or photodetector flicker noise, at least close to carrier. For high Fourier frequency offset, the achievable phase noise may be limited by the intrinsic phase noise of the OEO, RF amplifiers and the possible feedback bandwidth.

Referring back to FIG. 1, an OEO can be used as a precision tunable frequency synthesizer. Generally, to allow frequency tunability, the OEO can incorporate appropriate actuators (e.g., as disclosed with respect to FIGS. 10A-10C that allow phase locking to an appropriate frequency reference). In FIG. 1, a phase noise analyzer (PNA) as for example discussed with respect to FIGS. 2A, 2B, 3A, 3B and 8 can be used as a frequency reference.

The phase noise of the tunable OEO can then be to a large extent limited by the sensitivity of the PNA. A specific design example of a frequency synthesizer based on a tunable OEO is shown in FIG. 11. The system 1100 comprises a tunable OEO 102a and a high sensitivity phase noise analyzer 104. A tunable microwave source based on a generic tunable DUT was already discussed with respect to FIG. 8. The phase noise of the OEO is measured by the PNA 104 in real time, and fed back to the OEO 102a for suppression of phase noise. An appropriate PNA was for example described with respect to FIG. 2B. As discussed with respect to FIG. 2B, the PNA is preferably based on the delayed self-heterodyne method in conjunction with sensitivity enhancement via the use of higher order comb modes from an electro-optic comb to enable ultra-high sensitivity phase noise measurements.

The oscillation frequency of the tunable OEO 102a in FIG. 11 can be coarsely selected by the passband of a YIG filter 1102, and the oscillation frequency can be determined by the integer multiple of the inverse of the “effective” loop delay. Note that the “effective” loop delay can be tuned by changing, e.g., the optical/RF power and the optical wavelength through OEO oscillation dynamics. When the OEO 102a is locked to the PNA 104, the bias voltage for the intensity modulator (IM 1104) and current for the YIG filter 1102 can be modulated for fast and slow modulation, respectively. Any components, which can rapidly modulate optical/RF power, are sufficient for fast modulation of the OEO oscillation frequency such as for example an acousto-optic modulator (AOM) or an additional intensity modulator outside the OEO loop. The OEO oscillation frequency can be changed, depending on the current applied to the YIG filter. The tuning steps can correspond to the inverse of the loop delay (˜1 MHz in the present example). In some applications, OEO tuning can also be facilitated by the implementation of microwave photonic filters, for example, in the form of two time delayed electro-optic modulators with an optical bandpass filter, as previously described with respect to FIGS. 10A, 10B and 10C. Other forms of microwave photonic filters can also be used.

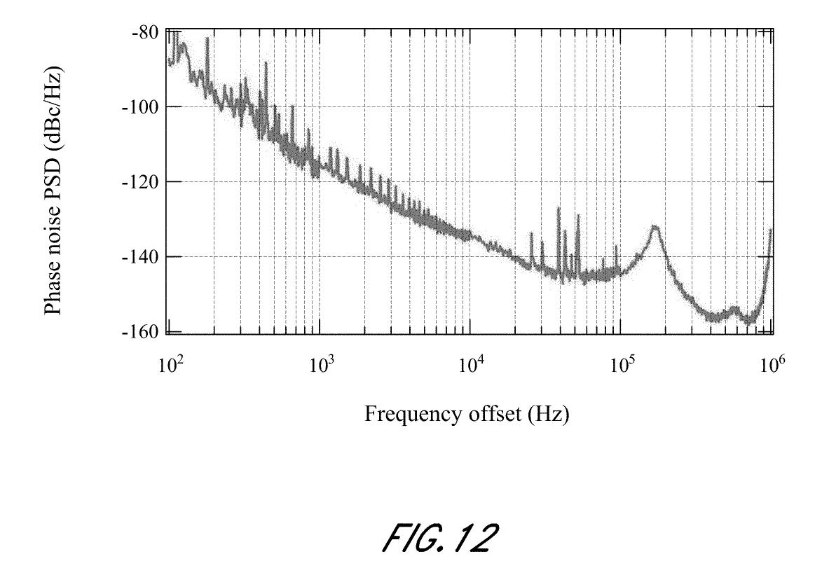

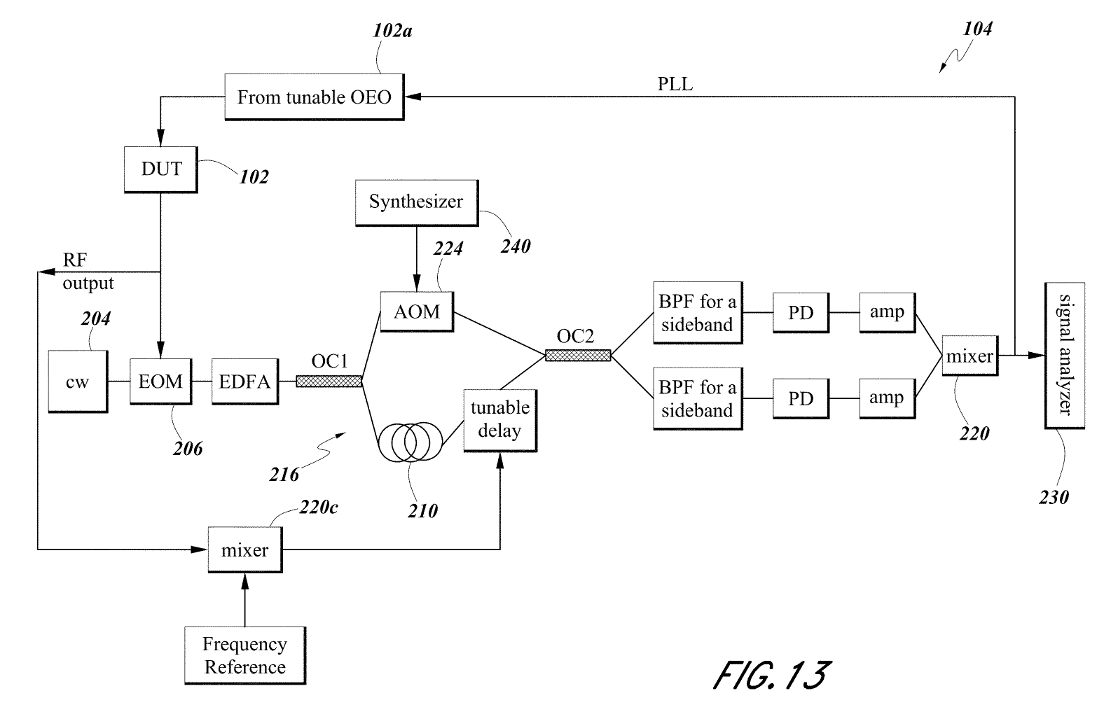

The bandwidth of the photo detector 1106 may set the upper limit for the maximum achievable oscillation frequency of the OEO. Appropriate frequency references based on PNAs were previously discussed for example with respect to FIGS. 2A and 2B. In the present example shown in FIG. 11, the unbalanced Mach-Zehnder interferometer (MZI) 216 in the PNA 104 contains a fiber delay line 210 with a length of ˜200 m. For locking of the OEO to the PNA, the output from the PNA is used as an error signal, and fed back to the OEO. An example of the obtained phase noise of the locked OEO is shown in FIG. 12, where a phase noise of −89 dBc/Hz, −115 dBc/Hz, −135 dBc/Hz, and −143 dBc/Hz at 100 Hz, 1 kHz, 10 kHz, and 100 kHz Fourier offset frequency for a 10 GHz carrier is achieved, respectively. To constitute a frequency synthesizer, the OEO oscillation frequency ideally can be continuously tunable and preferably the oscillation frequency can further be locked to a universal frequency standard such as the global positioning system (GPS). For continuous tuning of the OEO oscillation frequency the delay in the unbalanced MZI 210 in the PNA 104 can be changed, while the OEO 102a is locked to the PNA 104. However, the tuning range may then be limited by mode-hops inside the OEO. To enable continuous tuning, the continuous tuning range is preferably larger than the frequency spacing between individual modes of the OEO (˜1 MHz in the present example). Continuous tuning in such a large frequency range can be achieved by simultaneously changing the delay in the OEO and the PNA by a similar amount; thus the fundamental frequency of a selected mode follows the frequency defined by the PNA.

Also, for large tuning ranges, the optical bandpass filters OBPF1 and OBPF2 of the PNA 104 shown in FIG. 11 can be adjusted, as their bandwidth is typically only about 5 GHz, whereas the location of the required optical passband of the filters can be moved by 100 GHz when tuning the OEO frequency from 10-20 GHz and using the ±10th mode of the phase modulator (PM) inside the PNA 104 for phase noise analysis. However, the required filter movement can be automated with previous calibration of the OEO operation frequencies. A variety of different filter designs can be implemented for OBPF1 and OBPF2, for example, narrow bandwidth optical filters, Fabry-Perot filters, fiber coupled Fabry-Perot filters or fiber gratings. Any of these filters can be tuned, for example, tuning can be performed mechanically, via the use of PZTs, stress variations or thermally.

Because the delay tuning range of the OEO and PNA in the system 1100 may be limited, mode-hops can occur, but any frequency inside the OEO tuning range can be selected because of overlap between the free spectral range of the OEO and the mode hop free tuning range.

Delay tuning can be provided by appropriate delay stages, adjustable microelectromechanical system (MEMS) mirrors, voice coils or by coiling some of the fiber onto a piezo-electric fiber drum. The OEO frequency can additionally or alternatively be tuned electronically via the inclusion of a chirped fiber Bragg grating in the OEO loop and tuning of the cw laser frequency.

PNAs are good frequency references for short term stability (<1 s), but may not be a good reference for long term stability (>1 s). To achieve good long term stability, the oscillation frequency can be locked to an external frequency reference, for example a universal frequency standard such as GPS. This is further explained with respect to FIG. 13. In FIG. 13, the tunable OEO 102a is locked to a phase noise analyzer PNA 104, which comprises an unbalanced MZI 216. Appropriate PNAs were for example discussed with respect to FIGS. 2A, 2B, 3A, 3B and 8; another example embodiment of such a PNA 104 is shown in FIG. 13. The frequency reference in FIG. 13 can be a microwave signal derived from GPS or any other frequency reference. For referencing of the OEO frequency to the frequency reference, the microwave output from the OEO can be phase-compared with the frequency reference through an RF mixer 220c. An output from the RF mixer 220c can then be used as an error signal and fed back to the tunable (fiber) delay 210 in the PNA 104.

To reduce spurs or resonances in the OEO, a dual-loop configuration can be used. To adapt a dual loop as a frequency synthesizer, the delay in both loops can be adjusted simultaneously.

Although a specific example (e.g., 200 m fiber for both OEO and PNA) is shown here, the fiber delay 210 in the PNA can be appropriately chosen according to which Fourier frequency offset is most important for a given application. Generally, a longer fiber delay is preferable for lower frequency offset.

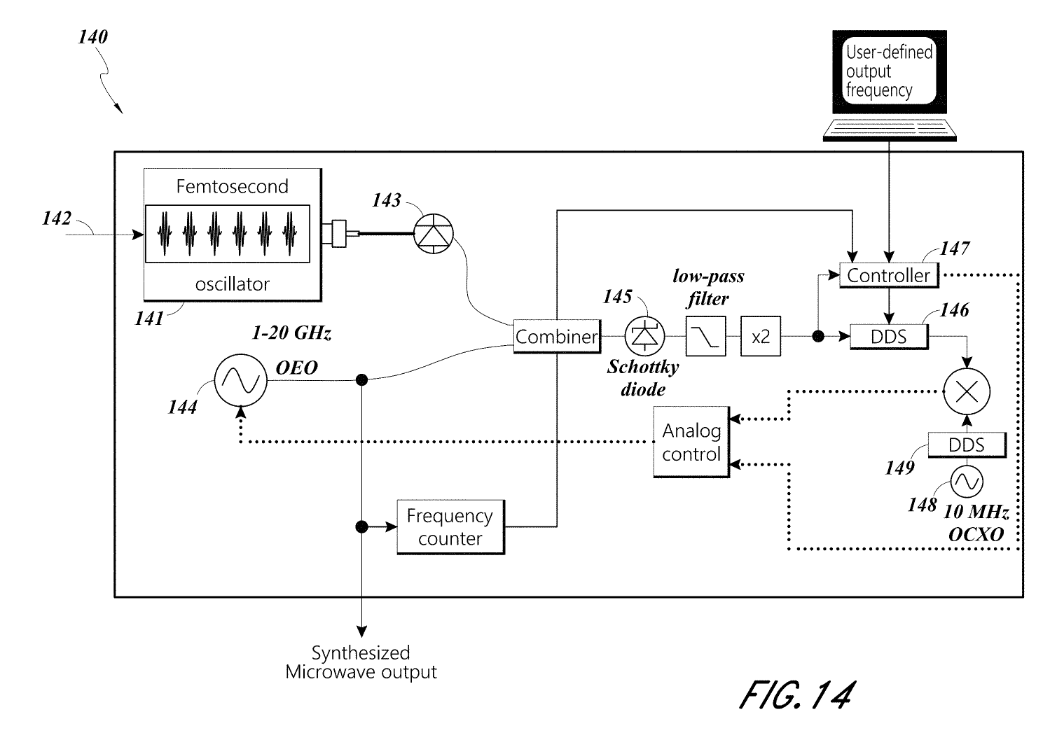

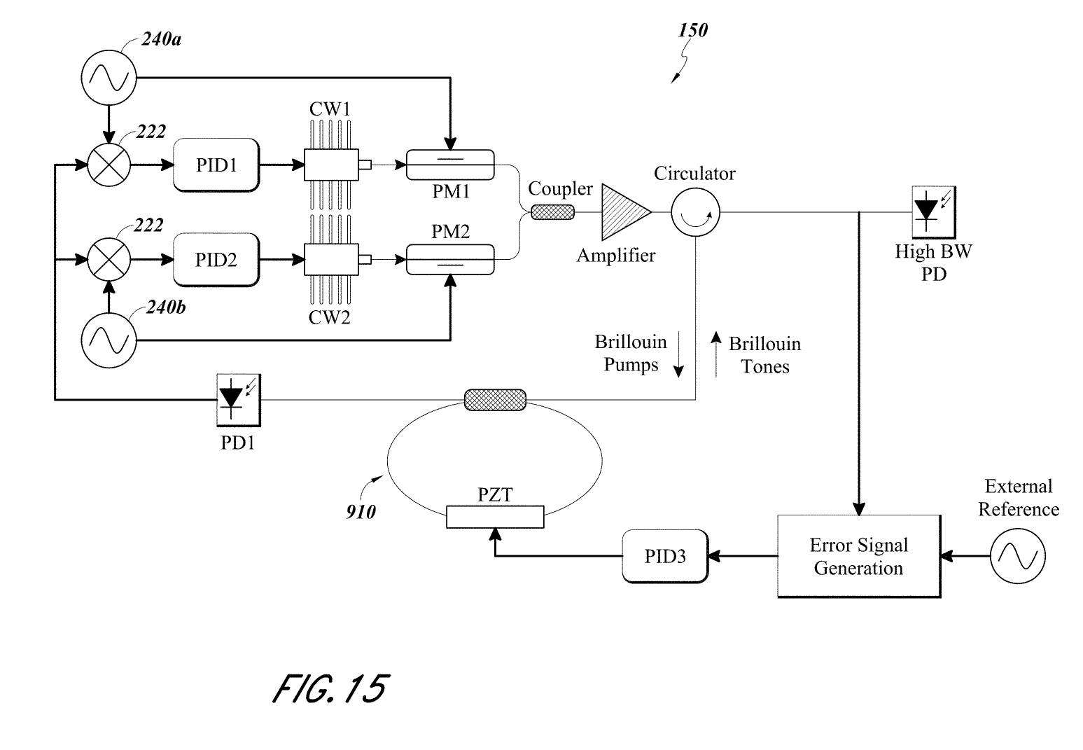

To increase the sensitivity of the PNA, it can be useful to use EO comb modes even beyond, e.g., the ±10th mode. Such broad EO combs can be generated via the use of cascaded EOMs rather than a single EOM 206 as shown in FIG. 14. Appropriate phase shifters can be used between the cascaded EOMs to maximize the bandwidth of the generated EO comb. Also, further spectral broadening in highly nonlinear fibers can be used via sections of highly nonlinear fiber inserted after the EOMs.

For ultimate precision in frequency synthesis, referencing of the OEO to a frequency standard such as GPS as discussed with respect to FIG. 13 may not be adequate for some applications. Even better frequency resolution can for example be achieved by referencing the OEO to an optical frequency reference with the help of an optical frequency comb. An example system 140 is shown in FIG. 14. An ultra-stable laser or an optical clock can serve as an optical input reference for microwave frequency synthesis, where a self-referenced optical frequency comb 141 is stabilized to the optical clock reference 142. Referencing of the comb to an optical clock can be implemented, for example, via locking one of the comb lines to the optical clock. A high bandwidth photodetector 143 detects the stabilized optical pulse train. For ultimate precision, the photodetection can be based on a low flicker noise photodiode or a balanced optical-microwave phase detector to reduce or minimize the AM-PM induced phase noise. The microwave harmonics detected carry the stability of the optical reference. A tunable OEO 144, as for example discussed with respect to FIGS. 10A and 11, then allows for tunable microwave generation (e.g., in a range from about 1 GHz to 70 GHz).

The microwave frequency comb generated in photodiode 143 and the tunable OEO 144 can be combined by a combiner and down-converted using a fast Schottky diode 145. A beatnote (in the microwave domain) between the OEO and one harmonic of the microwave comb can be further isolated with a low-pass filter, with a cut-off frequency at half of the frequency of the comb repetition rate, which reduces or eliminates the contribution from the other harmonics. The beatnote can be further multiplied by a factor of two to drive a DDS 146. The DDS division ratio can be set by a controller 147 (e.g., a field programmable gate array (FPGA) or microprocessor) in order to set the beatnote to, for example, 10 MHz to compare it with an ultra-low noise 10 MHz oven-controlled crystal oscillator (OCXO) 148. In case the beatnote is lower than 10 MHz, the OCXO 148 can drive an additional DDS 149 in order to match the frequency of the DDS 146 (now set to a fixed division ratio of 2). This technique follows the idea of a fractional/integer-N phase locked loop. As a result the phase difference between the tunable OEO 144 and the optical reference 142 any beatnote frequency from DC to half of the repetition rate frequency can be retrieved. This phase error can be transformed to an error signal with a phase detector, which can be used to generate appropriate control signals for frequency control of the tunable OEO 144 via appropriate PID loops or lead-lag controllers. The control signals can for example control the slow and fast actuators inside the tunable OEO 144, examples of which were discussed with respect to FIGS. 10A and 11.

For selection of a particular, but arbitrary frequency, the following procedure can be implemented. A frequency is chosen and communicated to the system 140 (shown as a user-defined output frequency in FIG. 14). A low-resolution microwave frequency counter then measures the frequency of the OEO and sends the frequency information to the controller. The controller 147 sends an order to the slow actuator of the OEO 144 to get the OEO oscillation close to the requested frequency. The mode number, beating with the OEO, of the microwave comb can then be calculated by the controller, which sets the appropriate DDS division ratio.

For example, if the requested frequency is 10,050,001,000.002210 Hz, a kHz-resolution frequency counter and the controller can set the OEO to approximately that frequency (e.g., 10,050,001 kHz). The beatnote is then measured by the controller 147. For example, for a 250 MHz frequency comb, the microwave mode number is 40 and the beatnote can be at a frequency of 50,001,000.002210 Hz. As the beatnote is multiplied by 2 (e.g., to properly clock the DDS), the division is set by the controller to be 10.000200000442. The output of the DDS 149 is then a synthesized beatnote at 10 MHz and can be compared to the OCXO 148 to generate an error signal.

Embodiments of the DC −70 GHz synthesizer can provide μHz frequency resolution with the use of state-of-the-art electronic components. This system 140 allows the transfer of the reference frequency from an ultra-stable cavity or an optical clock down to a stability of about 10⁻¹⁷ at 1 s averaging time (e.g., −140 dBc/Hz at 1 Hz) to the microwave domain (e.g., DC −70 GHz).

To extend precision frequency synthesis beyond the tuning range of OEOs, e.g., beyond 50 or 100 GHz, the heterodyne source as discussed with respect to FIG. 9C can also be conveniently adapted. For illustrative purposes, a set-up based on the generation of two Brillouin tones with a single fiber cavity is shown in FIG. 15. For frequency synthesis with a heterodyne source, for example, an arrangement as shown in FIG. 15 can be used.

In an example system 150, two independent cw lasers cw1, cw2 are combined and subsequently amplified to enable the onset of Brillouin oscillation in the fiber cavity. The amplified cw lasers are then injected into a Brillouin cavity through a circulator, which separates the input signal and the reflected signal into different optical paths. The Brillouin cavity 910 can be similar to the cavity 910 described with reference to FIG. 9C. The cavity 910 can comprise for example a fiber ring (as shown in FIG. 15), or any other cavity that may facilitate the generation of Brillouin tones by allowing the pump to be in resonance with the cavity. In order to provide a degree of freedom to control the free spectral range (FSR) of the cavity 910, an actuator, for example a PZT shown in FIG. 15, can be installed in the cavity. In order to clamp the frequency of the cw lasers to individual modes of the cavity (or vice versa), a variety of locking techniques can be applied. When implementing the PDH method, as for example shown in FIG. 15, the two cw lasers cwl, cw2 are modulated by two phase modulators PM1 and PM2 (placed in between the cw lasers and the coupler) driven by two different PDH driving signals at frequencies f1 and f2 (e.g., generated by the synthesizers 240a, 240b). The residual Brillouin pump signal can be detected by a photodetector PD1 and subsequently split and filtered with two RF filters centered near f1 and f2. The error signal, generated by mixing the photodetected signals at f1 and f2 with the PDH driving signals, and subsequent loop-filtering, can be fed back to either the cw laser or the Brillouin cavity. For the former case, the cw laser can be locked to the Brillouin cavity, whereas in the latter case the cavity can follow the cw laser. Separate proportional-integral-derivative (PID) controllers PID1, PID2 can be used for control of each laser cw1, cw2, respectively.

In the example shown in FIG. 15, both correction signals are fed to the cw lasers, resulting in two independent cw lasers locked to two different Brillouin cavity resonances. The two generated Brillouin tones, which propagate in opposite directions to the pump signals, are phase-noise-suppressed by the Brillouin effect at higher offset frequencies and strongly correlated at lower offsets following the fluctuation of the FSR of the Brillouin cavity.

The two Brillouin tones can be directly heterodyned against each other in a high bandwidth photodetector (High BW PD) to generate millimeter and terahertz waves (where the generated frequency is determined by the separation of the two cw lasers). Alternatively, the heterodyne frequency can be compared with a frequency reference to generate an error signal, which can be used to further stabilize the drift of the FSR of the Brillouin cavity 910 by feeding back to an actuator in the cavity (for example, the PZT shown in FIG. 15) controlled by PID3. The method deployed to generate the error signal can include, for example, directly mixing the beat signal of the two Brillouin tones with a high frequency reference signal, or mixing a low frequency signal, which can be generated by modulating the two Brillouin tones and beating two higher order sidebands (for example, generated by an appropriate electro-optic modulator), with a low frequency reference. The generation of higher order beat signals via electro-optic modulation of a cw laser or in a highly nonlinear fiber can be implemented.

Once the system 150 is stabilized to an external reference, the generated millimeter or terahertz wave has significantly reduced phase noise in both low and high frequency offsets compared with that generated from beating two free-running cw lasers.

To reduce the phase noise of the heterodyne source 150 even further, an additional phase noise analyzer as shown in FIG. 9C can be used. Referring back to FIG. 9C, to lock the generated heterodyne frequency to an external frequency reference, it is useful to distinguish the available frequency reference and actuators. For example, in the system 150, the four actuators include: (1a) frequency control of cw1, (2a) frequency control of cw2, (3a) length control of the Brillouin cavity, and (4a) length control of the PNA. The system 150 includes, e.g., five frequency references (1r) cw1, (2r) cw2, (3r) the Brillouin cavity, (4r) the PNA, and (5r) the external frequency reference. Some or all of the individual actuators can in turn comprise coarse and fine control, for example, two PZTs of different length to allow for short term and long term locking. For illustrative purposes, coarse and fine controls are not described separately. However, it is assumed that each actuator can have the capability for coarse and/or fine control.

As an example of locking the heterodyne frequency to an external frequency reference (5r), the following locking scheme can be implemented:

1) Lock (1r) to (4r) via (1a);

2) Lock (2r) to (3r) via (2a);

3) Lock (3r) to (1r) via (3a); and

4) Lock (4r) to (5r) via (4a)

As another example, where (5r) is the external frequency reference, (4r) is locked to (5r); (1r) is locked to (4r); (3r) is locked to (1r), and finally (2r) is locked to (3r). In this example, all frequencies can be traced back to the absolute frequency reference (5r). Other permutations for tracing all five frequencies back to the absolute frequency reference (5r) are also possible.

Another example of a locking scheme includes:

1) The first cw laser cw1 can be locked to the PNA via modulation of the frequency of the first cw laser.

2) The second cw laser cw2 can be locked to the Brillouin cavity 910 via modulation of the frequency of the second cw laser.

3) The Brillouin cavity 910 can then be locked to the laser cw1 via modulation of the Brillouin cavity length via the PZT in the cavity 910.

4) For locking to the external frequency reference, the PNA can be locked to the external reference via modulation of the delay length in the PNA. The capability for delay length tuning can be implemented by the tunable delay within the fiber delay line of the interferometer 216 (see, e.g., FIG. 3A).

An error signal can be provided between the generated microwave frequency as well as the external frequency reference. This can be done via frequency mixing as discussed with reference to FIG. 15. Via an appropriate PID control, long-term locking of the heterodyne frequency source to the external frequency reference is possible via, for example, control of the fiber delay length in the PNA, e.g., locking (4r) to (5r) via (4a). Low phase noise millimeter waves up to frequencies as high as 1 THz with precisely defined frequency can be generated with this scheme.

### Additional Aspects

In a first aspect, a phase noise analyzer comprises a continuous wave (cw) laser, said continuous cw laser characterized by a carrier frequency, an optical modulator imparting at least one optical sidebands at a modulation frequency onto the cw laser carrier frequency, said modulator being driven by a microwave oscillator signal under test, thereby converting said microwave oscillator signal into an optical signal; an imbalanced optical interferometer comprising two arms of non-equal length and further comprising at least one input port and two output ports, further configured to receive said optical signal into the at least one input port, and said two output ports comprising substantially the optical signal and a time delayed version of the optical signal in each of the two output ports; at least two optical filters located downstream from said two output ports of said imbalanced optical interferometer, said at least two optical filters configured such that a first optical filter passes a 1st frequency from one output port and a second optical filter passes a 2nd frequency from said other output port, said 2nd frequency differing from said 1st frequency by at least said modulation frequency or a multiple thereof, at least one photodetector located downstream from each of said optical filters converting the optical signal passed by said optical filters back to the electrical domain, thereby producing two electrical signals; a radio frequency (RF) mixer configured to receive said two electrical signals as input and produce an output containing phase noise information of said microwave oscillator signal; and a signal analyzer configured to analyze the noise of said microwave oscillator signal. The 1st frequency can comprise multiple frequencies, and the 2nd frequency can comprise multiple frequencies. The two electrical signals can comprise multiple electrical signals, e.g., at least two electrical signals.

In a second aspect, the phase noise analyzer according to aspect 1, further comprising at least a second modulator configured to impart an additional frequency shift in one of the two arms of said imbalanced optical interferometer.

In a third aspect, the phase noise analyzer according to aspect 1 or aspect 2, wherein the imbalanced optical interferometer further comprises a variable optical delay line to provide a tunable delay for the time delay between said two arms of said optical interferometer.

In a fourth aspect, the phase noise analyzer according to aspect 3, further comprising a phase locked loop configured to provide operation at quadrature phase difference at the RF mixer.

In a fifth aspect, the phase noise analyzer according to any one of aspects 1 to 4, wherein the at least one optical sideband comprises a +Nth order sideband or a −Nth order sideband, with N being 0 or a positive integer. The positive integer can be less than or equal to 3, less than or equal to 6, less than or equal to 10, or less than or equal to 20. For example, N can be 1, 2, 3, 4, 5, 6, 7, 8, 9, 10, 11, 12, 15, 20, 30, or more.

In a sixth aspect, the phase noise analyzer according to any one of aspects 1 to 5, wherein the at least one optical sideband comprises two optical sidebands encompassing any of the sidebands in a range from the +Nth order and −Nth order sideband, with N being a positive integer greater than or equal to 1. For example, N can be less than 5, less than 10, less than 20, or less than 30.

In a seventh aspect, the phase noise analyzer according to any one of aspects 1 to 6, wherein the optical interferometer comprises a plurality of delay lines of different lengths.

In an eighth aspect, the phase noise analyzer according to aspect 7, further comprising a switch configured to switch among the plurality of delay lines.

In a ninth aspect, the phase noise analyzer according to aspect 7 or aspect 8, wherein the plurality of delay lines comprises delay line lengths in a range from 30 km to 30 m.

In a 10th aspect, a multichannel phase noise analyzer comprising first and second phase noise analyzers, having respective first and second cw lasers, optical modulators, imbalanced interferometers, optical filters, photodetectors, and mixers each according to any one of aspects 1 to 9, said first and second phase nose analyzers generally arranged in similar order to each other. The first and second optical modulators are operatively connected to a common device under test which provides a signal to drive each of said optical modulators, and the multichannel phase noise analyzer comprises a multichannel signal analyzer operably arranged for cross correlation and signal averaging. One example of aspect 10 is a multichannel phase noise analyzer that comprises a first phase noise analyzer according to any one of aspects 1 to 9; a second phase noise analyzer according to any one of aspects 1 to 9; wherein a first optical modulator of said first phase noise analyzer and a second optical modulator of said second phase noise analyzer are operatively connected to a common device under test configured to provide said microwave oscillator signal under test to each of said optical modulators, and wherein said multichannel phase noise analyzer comprises a multichannel signal analyzer operably arranged for cross correlation and signal averaging

In an 11th aspect, the multichannel phase noise analyzer according to aspect 10, wherein said analyzer is arranged for operation in a range of about 1 GHz to 100 GHz.

In a 12th aspect, the multichannel phase noise analyzer according to aspect 10 or aspect 11, wherein said multichannel phase noise analyzer is configured for FFT analysis.

In a 13th aspect, a low phase noise microwave source comprises at least one continuous wave (cw) laser, said cw laser characterized by a carrier frequency, an optical modulator imparting at least one optical sideband at a modulation frequency onto the cw laser carrier frequency, said modulator being driven by a microwave oscillator under test, thereby converting a microwave oscillator signal into an optical signal; an imbalanced optical interferometer comprising two arms of non-equal length and further comprising at least one input port and two output ports, said imbalanced optical interferometer configured to receive said optical signal into its at least one input port, and to output substantially the optical signal and a time delayed version of the optical signal in each of the two output ports; at least two optical filters located downstream from said two output ports, further configured such that one filter passes a 1st frequency from one output port and said other filter passes a 2nd frequency from said other output port, said 2nd frequency differing from said 1st frequency by at least said modulation frequency or a multiple thereof, at least one photodetector located downstream from each of said optical filters and configured to convert the optical signal passed by said optical filters back to the electrical domain, thereby producing two electrical signals; a radio frequency (RF) mixer configured to receive said two electrical signals as input and producing an output containing phase noise information of said microwave oscillator signal; and a feedback loop configured to use the output of said RF mixer as an error signal and to feed back a control signal to said microwave oscillator under test, thereby reducing the phase noise of said microwave oscillator. The 1st frequency can comprise multiple frequencies, and the 2nd frequency can comprise multiple frequencies. The two electrical signals can comprise multiple electrical signals, e.g., at least two electrical signals.

In a 14th aspect, a low phase noise microwave source comprises a 1st continuous wave (cw) laser configured to generate a first optical signal characterized by a 1st carrier frequency; a 2nd cw laser configured to generate a second optical signal characterized by a 2nd carrier frequency; a four-port coupler configured to optically combine the first and second optical signals at said 1st and 2nd carrier frequencies into a combined signal; an imbalanced optical interferometer comprising two arms of non-equal length and two input ports; the four-port coupler configured to inject the combined signal into the two inputs of said imbalanced optical interferometer, said interferometer further comprising two output ports, comprising substantially said combined signal and a time delayed version of said combined signal in each of the two output ports; at least two optical filters located downstream from said two output ports, configured such that one filter passes said 1st carrier frequency from one output port and said other filter passes said 2nd carrier frequency from said other output port, at least one photodetector located downstream from each of said optical filters and configured to convert the optical signal passed by said optical filters back to the electrical domain, thereby producing two electrical signals; a radio frequency (RF) mixer configured to receive said two electrical signals as input and to produce an output containing differential phase noise information between said two cw lasers; a feedback loop configured to use the output of said RF mixer as an error signal and to feed back a control signal to at least one of said cw lasers, thereby reducing the differential phase noise between said 1st and 2nd cw lasers. The two electrical signals can comprise two or more than two electrical signals.

In a 15th aspect, the phase noise analyzer of any one of aspects 1-9, wherein the microwave oscillator signal under test is generated by a dielectric resonator oscillator (DRO), a tunable opto-electronic oscillator (OEO), or a tunable coupled OEO (COEO).

In a 16th aspect, the multichannel phase noise analyzer of any one of aspects 10-12, where the common device under test comprises a dielectric resonator oscillator (DRO), a tunable opto-electronic oscillator (OEO), or a tunable coupled OEO (COEO).

In a 17th aspect, the low phase noise microwave source of aspect 13, wherein the microwave oscillator under test comprises a dielectric resonator oscillator (DRO), a tunable opto-electronic oscillator (OEO), or a tunable coupled OEO (COEO).

In an 18th aspect, the low phase noise microwave source of aspect 14, wherein said 1st and 2nd cw lasers are derived from two separate Brillouin cavities each pumped by one cw pump laser each, said 1st and 2nd cw lasers operating at two different carrier frequencies, the source further comprising at least one actuator operatively connected to said feedback loop to reduce the relative phase noise between said 1st and 2nd cw lasers.

In a 19th aspect, the low phase noise microwave source of aspect 14, wherein the 1st and the 2nd cw lasers are further configured to pump a common Brillouin cavity, said Brillouin cavity producing two output tones at two different frequencies, said two output tones being further directed to at least one additional photodetector for the generation of a low phase noise microwave signal via heterodyning of the two output tones.

In a 20th aspect, a low phase noise microwave source comprises a phase noise analyzer (PNA) comprising a self-heterodyne system configured with sensitivity enhancement via an electro-optic comb driven by said microwave source, said PNA further comprising a fiber delay line; and an electronic feedback loop configured to use an output of said PNA and feed a signal back to said microwave source, thereby reducing the phase noise of said microwave source.

In a 21st aspect, a low phase noise microwave source according to aspect 20, comprising a dielectric resonator oscillator (DRO), a tunable opto-electronic oscillator (OEO), or a tunable coupled OEO (COEO).

In a 22nd aspect, a low phase noise microwave source comprising: a phase noise analyzer (PNA) comprising a self-heterodyne system configured with sensitivity enhancement via an electro-optic comb driven by said microwave source, said PNA further comprising a fiber delay line and 1st and 2nd continuous wave (cw) lasers; and a feedback loop configured to use an output of said PNA as an error signal and to feed back a control signal to at least one of said 1st and 2nd cw lasers, thereby reducing differential phase noise between said 1st and 2nd cw lasers.

In a 23rd aspect, a low phase noise microwave source according to aspect 22, wherein said 1st and 2nd cw lasers are derived from two separate Brillouin cavities each pumped by a cw pump laser, said 1st and 2nd cw lasers operating at two different carrier frequencies, the low phase noise microwave source further comprising at least one actuator operatively connected to said feedback loop to reduce the relative phase noise between said 1st and 2nd cw lasers.

In a 24th aspect, a low phase noise microwave source according to aspect 22 or aspect 23, wherein the 1st and the 2nd cw lasers are further configured to pump a common Brillouin cavity, said common Brillouin cavity configured to produce two output tones at two different frequencies, said common Brillouin cavity configured to direct said two output tones to at least one additional photodetector for the generation of a low phase noise microwave signal via heterodyning of the two output tones.

In a 25th aspect, a frequency synthesizer in the microwave domain, the frequency synthesizer comprising a tunable opto-electronic oscillator (OEO) configured to generate a microwave signal; a phase noise analyzer (PNA) comprising a self-heterodyne system configured with sensitivity enhancement via an electro-optic comb driven by said microwave signal, said PNA further comprising a fiber delay line; and an electronic control loop, wherein said frequency synthesizer is configured to lock a frequency of the microwave signal generated by said OEO to said PNA via said electronic control loop.

In a 26th aspect, a frequency synthesizer according to aspect 25, wherein: said OEO comprises at least one actuator configured to control the frequency of the microwave signal generated by said OEO via said electronic control loop.

In a 27th aspect, a frequency synthesizer according to aspect 25 or aspect 26, wherein said OEO comprises a tunable microwave filter.

In a 28th aspect, a frequency synthesizer according to aspect 27, wherein said tunable microwave filter comprises an yttrium iron garnet (YIG) filter.

In a 29th aspect, a frequency synthesizer according to aspect 27 or aspect 28, wherein said microwave filter comprises a microwave photonic filter.

In a 30th aspect, a frequency synthesizer according to any one of aspects 25 to 29, wherein said OEO further comprises an actuator configured to control optical or radio frequency (RF) power that circulates inside said OEO.

In a 31st aspect, a frequency synthesizer according to aspect 30, wherein said OEO comprises an OEO loop, and said actuator is located either inside the OEO loop or external to said OEO loop.

In a 32nd aspect, a frequency synthesizer according to aspect 30 or aspect 31, wherein said actuator comprises an electro-optic or an acousto-optic modulator.

In a 33rd aspect, a frequency synthesizer according any one of aspects 25 to 32, wherein said OEO further comprises an actuator configured to control a loop delay inside said OEO. The actuator can be configured to change the optical/RF power and/or the optical wavelength through OEO oscillation dynamics.

In a 34th aspect, a frequency synthesizer according to any one of aspects 25 to 33, wherein: said PNA further comprises an actuator configured to control a delay of said fiber delay line.

In a 35th aspect, a frequency synthesizer according to any one of aspects 25 to 34, said OEO further comprising an actuator configured to control a loop delay inside said OEO; and said PNA comprising an actuator configured to control a delay of said fiber delay line.

In a 36th aspect, a frequency synthesizer according to any one of aspects 25 to 35, said OEO further configured to frequency lock to an external microwave frequency reference.

In a 37th aspect, a frequency synthesizer according to aspect 36, wherein said external microwave frequency reference is derived from a global positioning system (GPS) reference signal.

In a 38th aspect, a frequency synthesizer according to aspect 36 or aspect 37, said OEO comprising: a mixer configured to mix a microwave signal from the external microwave frequency reference with the microwave signal generated by said OEO, thereby generating an error signal, said OEO configured to control a delay inside said fiber delay line based at least in part on said error signal.

In a 39th aspect, a frequency synthesizer for the microwave or millimeter (mm) wave domain, the frequency synthesizer comprising: a tunable heterodyne source configured to generate a signal in the microwave or mm wave domain, said heterodyne source comprising two continuous wave (cw) lasers, each cw laser locked to a different cavity mode of a Brillouin fiber laser; an electronic control loop; an actuator; an external frequency reference; and a mixer configured to mix the external frequency reference with said heterodyne source, thereby generating an error signal, said electronic control loop and said actuator configured to control a cavity length of said Brillouin fiber laser based at least partly on said error signal.

In a 40th aspect, a frequency synthesizer according to aspect 39, said mixer configured to mix a secondary heterodyne signal derived from said heterodyne source with said external frequency reference thereby generating a second error signal, said secondary heterodyne signal having a lower frequency than said heterodyne source, said electronic control loop and said actuator configured to control the cavity length of said Brillouin fiber laser based at least partly on said second error signal.

### Additional Information

Example, non-limiting experimental data are included in this specification to illustrate results achievable by various embodiments of the systems and methods described herein. All ranges of data and all values within such ranges of data that are shown in the figures or described in the specification are expressly included in this disclosure. The example experiments, experimental data, tables, graphs, plots, figures, and processing and/or operating parameters (e.g., values and/or ranges) described herein are intended to be illustrative of operating conditions of the disclosed systems and methods and are not intended to limit the scope of the operating conditions for various embodiments of the methods and systems disclosed herein. Additionally, the experiments, experimental data, calculated data, tables, graphs, plots, figures, and other data disclosed herein demonstrate various regimes in which embodiments of the disclosed systems and methods may operate effectively to produce one or more desired results. Such operating regimes and desired results are not limited solely to specific values of operating parameters, conditions, or results shown, for example, in a table, graph, plot, or figure, but also include suitable ranges including or spanning these specific values. Accordingly, the values disclosed herein include the range of values between any of the values listed or shown in the tables, graphs, plots, figures, etc. Additionally, the values disclosed herein include the range of values above or below any of the values listed or shown in the tables, graphs, plots, figures, etc. as might be demonstrated by other values listed or shown in the tables, graphs, plots, figures, etc. Also, although the data disclosed herein may establish one or more effective operating ranges and/or one or more desired results for certain embodiments, it is to be understood that not every embodiment need be operable in each such operating range or need produce each such desired result. Further, other embodiments of the disclosed systems and methods may operate in other operating regimes and/or produce other results than shown and described with reference to the example experiments, experimental data, tables, graphs, plots, figures, and other data herein.

Thus, the invention has been described in several non-limiting embodiments. It is to be understood that the embodiments are not mutually exclusive, and elements described in connection with one embodiment may be combined with, rearranged, or eliminated from other embodiments in suitable ways to accomplish desired design objectives. No single feature or group of features is necessary or required for each embodiment. All possible combinations and sub-combinations of elements are included within the scope of this disclosure.

For purposes of summarizing the present invention, certain aspects, advantages and novel features of the present invention are described herein. It is to be understood, however, that not necessarily all such advantages may be achieved in accordance with any particular embodiment. Thus, the present invention may be embodied or carried out in a manner that achieves one or more advantages without necessarily achieving other advantages as may be taught or suggested herein.

As used herein any reference to “one embodiment” or “some embodiments” or “an embodiment” means that a particular element, feature, structure, or characteristic described in connection with the embodiment is included in at least one embodiment. The appearances of the phrase “in one embodiment” in various places in the specification are not necessarily all referring to the same embodiment. Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. In addition, the articles “a” or “an” or “the” as used in this application and the appended claims are to be construed to mean “one or more” or “at least one” unless specified otherwise.

As used herein, the terms “comprises,” “comprising,” “includes,” “including,” “has,” “having” or any other variation thereof, are open-ended terms and intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), or both A and B are true (or present). As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present.

Thus, while only certain embodiments have been specifically described herein, it will be apparent that numerous modifications may be made thereto without departing from the spirit and scope of the invention. Further, acronyms are used merely to enhance the readability of the specification and claims. It should be noted that these acronyms are not intended to lessen the generality of the terms used and they should not be construed to restrict the scope of the claims to the embodiments described therein.

What is claimed is:

1. A phase noise analyzer comprising:
a continuous wave (cw) laser, said continuous cw laser characterized by a carrier frequency,
an optical modulator imparting at least one optical sideband at a modulation frequency onto the cw laser carrier frequency, said modulator being driven by a microwave oscillator signal under test, thereby converting said microwave oscillator signal into an optical signal;
an imbalanced optical interferometer comprising two arms of non-equal length and further comprising at least one input port and two output ports, further configured to receive said optical signal into the at least one input port, and said two output ports comprising substantially the optical signal and a time delayed version of the optical signal in each of the two output ports;
at least two optical filters located downstream from said two output ports of said imbalanced optical interferometer, said at least two optical filters configured such that a first optical filter passes at least a 1st frequency from one output port and a second optical filter passes at least a 2nd frequency from said other output port, said 2nd frequency differing from said 1st frequency by at least said modulation frequency or a multiple thereof,
at least one photodetector located downstream from each of said at least two optical filters and configured to convert the optical signal passed by said at least two optical filters back to the electrical domain, thereby producing at least two electrical signals;
a radio frequency (RF) mixer configured to receive said at least two electrical signals as input and produce an output containing phase noise information of said microwave oscillator signal; and
a signal analyzer configured to analyze the noise of said microwave oscillator signal.

2. A phase noise analyzer according to claim 1, further comprising at least a second modulator configured to impart an additional frequency shift in one of the two arms of said imbalanced optical interferometer.

3. A phase noise analyzer according to claim 1, wherein the imbalanced optical interferometer further comprises a variable optical delay line to provide a tunable delay for the time delay between said two arms of said imbalanced optical interferometer.

4. A phase noise analyzer according to claim 3, further comprising a phase locked loop configured to provide operation at quadrature phase difference at the RF mixer.

5. A phase noise analyzer according to claim 1, wherein the at least one optical sideband comprises a +Nth order sideband or a −Nth order sideband, with N being 0 or a positive integer.

6. A phase noise analyzer according to claim 1, wherein said at least one optical sideband comprises two sidebands encompassing any of the sidebands in a range from the +Nth order and −Nth order sideband, with N being a positive integer greater than or equal to 1.

7. A phase noise analyzer according to claim 1, wherein the imbalanced optical interferometer comprises a plurality of delay lines of different lengths.

8. A phase noise analyzer according to claim 7, further comprising a switch configured to switch among the plurality of delay lines.

9. A phase noise analyzer according to claim 7, wherein the plurality of delay lines comprises delay line lengths in a range from 30 km to 30 m.

10. A phase noise analyzer according to claim 1, wherein the microwave oscillator signal under test is generated by a dielectric resonator oscillator (DRO), a tunable opto-electronic oscillator (OEO), or a tunable coupled OEO (COEO).

11. A multichannel phase noise analyzer comprising:
a first phase noise analyzer according to claim 1;
a second phase noise analyzer according to claim 1;
wherein a first optical modulator of said first phase noise analyzer and a second optical modulator of said second phase noise analyzer are operatively connected to a common device under test configured to provide said microwave oscillator signal under test to each of said optical modulators, and
wherein said multichannel phase noise analyzer comprises a multichannel signal analyzer operably arranged for cross correlation and signal averaging.

12. A multichannel phase noise analyzer according to claim 11, wherein said multichannel phase noise analyzer is arranged for operation in a range of about 1 GHz to 100 GHz.

13. A multichannel phase noise analyzer according to claim 11, wherein said multichannel phase noise analyzer is configured for fast Fourier transform (FFT) analysis.

14. A multichannel phase noise analyzer according to claim 11, where the common device under test comprises a dielectric resonator oscillator (DRO), a tunable opto-electronic oscillator (OEO), or a tunable coupled OEO (COEO).

15. A low phase noise microwave source comprising:
a phase noise analyzer (PNA) comprising a self-heterodyne system configured with sensitivity enhancement via an electro-optic comb driven by said microwave source, said PNA further comprising a fiber delay line; and
an electronic feedback loop configured to use an output of said PNA and feed a signal back to said microwave source, thereby reducing the phase noise of said microwave source.

16. A low phase noise microwave source according to claim 15, comprising a dielectric resonator oscillator (DRO), a tunable opto-electronic oscillator (OEO), or a tunable coupled OEO (COEO).

17. A low phase noise microwave source comprising:
a phase noise analyzer (PNA) comprising a self-heterodyne system configured with sensitivity enhancement via an electro-optic comb driven by said microwave source, said PNA further comprising a fiber delay line and 1st and 2nd continuous wave (cw) lasers; and
a feedback loop configured to use an output of said PNA as an error signal and to feed back a control signal to at least one of said 1st and 2nd cw lasers, thereby reducing differential phase noise between said 1st and 2nd cw lasers.

18. A low phase noise microwave source according to claim 17, wherein said 1st and 2nd cw lasers are derived from two separate Brillouin cavities each pumped by a cw pump laser, said 1st and 2nd cw lasers operating at two different carrier frequencies,
the low phase noise microwave source further comprising at least one actuator operatively connected to said feedback loop to reduce the relative phase noise between said 1st and 2nd cw lasers.

19. A low phase noise microwave source according to claim 17, wherein the 1st and the 2nd cw lasers are further configured to pump a common Brillouin cavity,
said common Brillouin cavity configured to produce two output tones at two different frequencies,
said common Brillouin cavity configured to direct said two output tones to at least one additional photodetector for the generation of a low phase noise microwave signal via heterodyning of the two output tones.
